(19) United States
(12) Patent Application Publication
(10) Pub. No.: US 2023/0080877 A1
(43) Pub. Date: Mar. 16, 2023

(54) ELECTROLUMINESCENT ELEMENT

(71) Applicant: Sharp Kabushiki Kaisha, Sakai City, Osaka (JP)

(72) Inventors: Masaki YAMAMOTO, Sakai City (JP); Hirohisa YAMADA, Sakai City (JP); Yoshihiro UETA, Sakai City (JP); Keisuke KITANO, Sakai City (JP); Kazuki GOTO, Sakai City (JP); Yusuke SAKAKIBARA, Sakai City (JP); Tadashi KOBASHI, Sakai City (JP); Masashi KAGO, Sakai City (JP); Soichiro NIKATA, Chikushino-city (JP); Yuko OGURA, Chikushino-city (JP); Masanori TANAKA, Chikushino-city (JP); Yuka TAKAMIZUMA, Chikushino-city (JP); Tetsuji ITO, Chikushino-city (JP)

(21) Appl. No.: 17/797,360

(22) PCT Filed: Feb. 17, 2020
(86) PCT No.: PCT/JP2020/006145

§ 371 Date: Aug. 3, 2022

(51) Int. Cl. H01L 51/50; H01L 51/00; C09K 11/88

(52) U.S. Cl. CPC H01L 51/502; H01L 51/0037; H01L 51/0035; C09K 11/883; H01L 51/5088; H01L 51/5072; H01L 2251/305

(57) ABSTRACT

The electroluminescent element includes an anode electrode, a cathode electrode, and a quantum dot (QD) layer including quantum dots and arranged between the anode electrode and the cathode electrode. The quantum dots are Cd-free quantum dots that include at least Zn and Se, and do not include Cd at a mass ratio of 1/30 or greater in relation to Zn. The particle size of each quantum dot is within a range from 3 nm to 20 nm.

### TECHNICAL FIELD

The disclosure relates to an electroluminescent element containing quantum dots (quantum dot phosphor particles).

### BACKGROUND ART

In recent years, various features related to electroluminescent elements containing quantum dots (quantum dot phosphor particles) have been developed. An example of such electroluminescent element is a quantum dot light-emitting diode (QLED).

Quantum dots containing cadmium (Cd) are commonly used as the quantum dots. However, Cd is internationally regulated due to its negative impact on the environment, and thus barriers for practical use are high. Therefore, in recent years, the development of Cd-free quantum dots that do not use Cd has also been examined. For example, the development of quantum dots based on chalcopyrite such as CuInS₂ and AgInS₂, and quantum dots based on indium phosphide (InP) is advancing (for example, see PTL 1).

### CITATION LIST

### Patent Literature

PTL 1: WO 2007/060889

### SUMMARY

### Technical Problem

However, the currently developed Cd-free quantum dots are not suitable as blue light-emitting quantum dots.

The external quantum efficiency (EQE) of an electroluminescent element in which Cd-free quantum dots are used is lower than the external quantum efficiency of an electroluminescent element in which Cd-containing quantum dots are used. In particular, the external quantum efficiency of an electroluminescent element in which Cd-free quantum dots that emit blue light are used is significantly lower than the external quantum efficiency of an electroluminescent element in which Cd-containing quantum dots are used.

One aspect of the disclosure was developed in light of the abovementioned problem, and an object thereof is to provide an electroluminescent element that uses Cd-free quantum dots that emit blue light and has a higher external quantum efficiency than known electroluminescent elements.

### Solution to Problem

To solve the above problem, the electroluminescent element according to one aspect of the disclosure includes an anode electrode, a cathode electrode, and a quantum dot light-emitting layer including quantum dots and provided between the anode electrode and the cathode electrode. The quantum dots are Cd-free quantum dots including at least Zn and Se and not including Cd at a mass ratio of 1/30 or greater in relation to Zn. A particle size of the quantum dots is within a range from 3 nm to 20 nm.

### Advantageous Effects of Disclosure

According to an electroluminescent element of one aspect of the disclosure, an electroluminescent element that uses Cd-free quantum dots that emit blue light and has a higher external quantum efficiency than known electroluminescent elements can be provided.

### BRIEF DESCRIPTION OF DRAWINGS

FIG. 1 is a cross-sectional view schematically illustrating an overall configuration of an electroluminescent element according to a first embodiment.

FIG. 2 is a schematic view illustrating an example of a quantum dot (QD) phosphor particle according to a first embodiment.

FIG. 3 is an image of a scanning electron micrograph of ZnSe obtained in Synthesis Example 1 of the QD phosphor particles of the first embodiment.

FIG. 4 is a graph of X-ray diffraction spectra of ZnSe and ZnSe/ZnS obtained in Synthesis Example 1 of the QD phosphor particles of the first embodiment.

FIG. 5 is a photoluminescence (PL) spectrum of ZnSe/ZnS obtained in Synthesis Example 1 of the QD phosphor particles of the first embodiment.

FIG. 6 is an image of a scanning electron micrograph of ZnSe/ZnS obtained in Synthesis Example 1 of the QD phosphor particles of the first embodiment.

FIG. 7 is a graph showing a relationship between the shell thickness and the fluorescence quantum yield of QD phosphor particles obtained in Example 4 of the first embodiment.

FIG. 8 is a graph showing a relationship between the shell thickness and the number of covering times with a shell.

FIG. 9 is a cross-sectional view schematically illustrating an overall configuration of main portions of a display device according to a second embodiment.

FIG. 10 is a diagram for describing a modified example of the display device according to the second embodiment.

FIG. 11 is a diagram for describing another modified example of the display device according to the second embodiment.

FIG. 12 is a diagram for describing a display device according to a third embodiment.

FIG. 13 is a diagram for describing a modified example of the display device according to the third embodiment.

### DESCRIPTION OF EMBODIMENTS

### First Embodiment

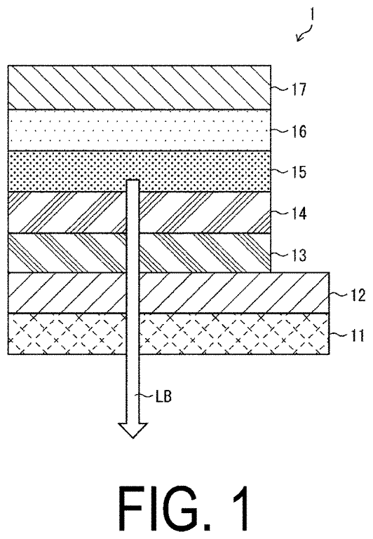

An electroluminescent element 1 according to a first embodiment will be described. Note that in the disclosure, a direction from an anode electrode 12 to a cathode electrode 17 in FIG. 1 is referred to as an upward direction, and the opposite direction thereof is referred to as a downward direction. In the disclosure, a horizontal direction is a direction (a main surface direction of each portion included in the electroluminescent element 1) perpendicular to a vertical direction. The vertical direction can also be referred to as a normal direction of each portion described above.

In the disclosure, a description of “from A to B” for two numbers A and B is intended to mean “equal to or greater than A and equal to or less than B”, unless otherwise specified.

### Structural Example of Electroluminescent Element

FIG. 1 is a cross-sectional view schematically illustrating an overall configuration of an electroluminescent element 1 according to the present embodiment.

The electroluminescent element 1 illustrated in FIG. 1 is an element that emits light when a voltage is applied to the quantum dot phosphor particles (quantum dot: QD, also referred to as semiconductor nanoparticle phosphors). Examples of the electroluminescent element 1 include a quantum dot light-emitting diode (QLED). Note that hereinafter, a quantum dot phosphor particle is abbreviated as a “QD phosphor particle”. The QD phosphor particle may also be referred to simply as a “quantum dot” or “QD”. In the present embodiment, the QD phosphor particles contained in the electroluminescent element 1 are blue QD phosphor particles.

The electroluminescent element 1 includes an anode electrode 12 (anode, first electrode), a cathode electrode 17 (cathode, second electrode), and a function layer provided between the anode electrode 12 and the cathode electrode 17. The function layer includes at least a QD layer 15 (quantum dot light-emitting layer, blue quantum dot light-emitting layer) containing QD phosphor particles. Note that in the present embodiment, the layers between the anode electrode 12 and the cathode electrode 17 are collectively referred to as a function layer.

The function layer may be a single layer type formed only of the QD layer 15, or may be a multi-layer type including a function layer in addition to the QD layer 15. Of the function layer, examples of function layers besides the QD layer 15 include a hole injection layer 13 (HIL), a hole transport layer 14 (HTL), and an electron transport layer 16 (ETL).

Additionally, each layer from the anode electrode 12 to the cathode electrode 17 is generally formed on a substrate used as a support body. Accordingly, the electroluminescent element 1 may be provided with a substrate as a support body.

As one example, the electroluminescent element 1 illustrated in FIG. 1 has a configuration in which a substrate 11, the anode electrode 12, the hole injection layer 13, the hole transport layer 14, the QD layer 15, the electron transport layer 16, and the cathode electrode 17 are layered in this order towards the upward direction of FIG. 1.

Thus, the QD layer 15 is interposed between the anode electrode 12 and the cathode electrode 17. In other words, the anode electrode 12 and the cathode electrode 17 are provided so as to sandwich the QD layer 15. Note that the electroluminescent element 1 may further include an electron injection layer between the QD layer 15 and the cathode electrode 17. For example, when the electroluminescent element 1 includes an electron transport layer 16 as illustrated in FIG. 1, the electroluminescent element 1 may include an electron injection layer between the electron transport layer 16 and the cathode electrode 17.

Hereinafter, each layer described above will be described in greater detail.

The substrate 11 is a support body for forming each layer from the anode electrode 12 to the cathode electrode 17, as described above. As illustrated in FIG. 1, the substrate 11 supports, thereon or thereabove, the anode electrode 12, the hole injection layer 13, the hole transport layer 14, the QD layer 15, the electron transport layer 16, and the cathode electrode 17.

The substrate 11 may be, for example, a glass substrate, or may be a flexible substrate such as a plastic substrate.

The electroluminescent element 1 may be used, for example, as a light source of an electronic device such as a display device. When the electroluminescent element 1 is part of a display device, for example, a substrate of the display device is used as the substrate 11. Thus, the electroluminescent element 1 may be referred to as an electroluminescent element 1 including the substrate 11, or may be referred to as an electroluminescent element 1 not including the substrate 11.

In this manner, the electroluminescent element 1 may itself include a substrate 11, or the substrate 11 of the electroluminescent element 1 may be a substrate of an electronic device such as a display device provided with the electroluminescent element 1. When the electroluminescent element 1 is part of a display device, for example, an array substrate on which a plurality of thin film transistors are formed may be used as the substrate 11. In this case, the anode electrode 12, which is a first electrode provided on the substrate 11, may be electrically connected to the thin film transistors of the array substrate.

In the case where the electroluminescent element 1 is, for example, part of a display device in this manner, the electroluminescent element 1 is provided on the substrate 11 for each pixel. Specifically, a red pixel (R pixel) is provided with an electroluminescent element (red electroluminescent element) that emits red light. A green pixel (G pixel) is provided with an electroluminescent element (green electroluminescent element) that emits green light. A blue pixel (B pixel) is provided with an electroluminescent element (blue electroluminescent element) that emits blue light. Accordingly, banks partitioning each pixel may be formed as pixel separation films such that electroluminescent elements can be formed on the substrate 11 for each R pixel, G pixel, and B pixel.

In the present embodiment, as described above, a case is described in which the electroluminescent element 1 illustrated in FIG. 1 is a blue electroluminescent element in which a QD layer 15 including blue quantum dots (blue QD phosphor particles) is used. However, the abovementioned red electroluminescent element is enabled by providing a QD layer containing red quantum dots (red QD phosphor particles) as the QD layer 15. Similarly, the abovementioned green electroluminescent element is enabled by providing a QD layer containing green quantum dots (green QD phosphor particles) as the QD layer 15.

In a bottom-emitting (BE) type electroluminescent element, light emitted from the QD layer 15 is emitted downward (i.e., towards the substrate 11 side). In a top-emitting (TE) type electroluminescent element, light emitted from the QD layer 15 is emitted upward (i.e., towards the side opposite the substrate 11). In a double-sided electroluminescent element, the light emitted from the QD layer 15 is emitted downward and upward.

In a case where the electroluminescent element 1 is a bottom emission (BE) type electroluminescent element or a double-sided electroluminescent element, the substrate 11 is constituted of a light-transmissive substrate made of a light-transmissive material. In a case where the electroluminescent element 1 is a top-emitting (TE) type electroluminescent element, the substrate 11 may be constituted of a light-transmissive material, or may be constituted of a light-reflective material.

Of the anode electrode 12 and the cathode electrode 17, the electrode serving as the light extraction surface side must be light-transmissive. Also note that the electrode of the side opposite the light extraction surface may or may not be light-transmissive.

For example, when the electroluminescent element 1 is a BE-type electroluminescent element, the electrode on the upper-layer side is a light-reflective electrode, and the electrode on the lower-layer side is a light-transmissive electrode. When the electroluminescent element 1 is a TE-type electroluminescent element, the electrode of the upper-layer side is a light-transmissive electrode, and the electrode of the lower-layer side is a light-reflective electrode. Note that the light-reflective electrode may be a layered body of a layer formed of a light-transmissive material and a layer formed of a light-reflective material.

In FIG. 1, as one example, a case is illustrated in which the electroluminescent element 1 is a BE-type electroluminescent element in which the anode electrode 12 is used as the electrode of the lower-layer side, the cathode electrode 17 is used as the electrode of the upper-layer side, and blue light LB emitted from the QD layer 15 is emitted downward. Therefore, a light-transmissive electrode is used as the anode electrode 12 such that the blue light LB emitted from the QD layer 15 can be transmitted therethrough. A light-reflective electrode is used as the cathode electrode 17 such that the blue light LB emitted from the QD layer 15 is reflected. Note that in the following description, the “blue light LB” is also abbreviated simply as “LB”. Other members will be similarly abbreviated as appropriate.

The anode electrode 12 is an electrode that supplies positive holes (holes) to the QD layer 15 when a voltage is applied. The anode electrode 12 includes for example, a material having a relatively large work function. Examples of the material include tin-doped indium oxide (ITO), zinc-doped indium oxide (IZO), aluminum-doped zinc oxide (AZO), gallium-doped zinc oxide (GZO), and antimony-doped tin oxide (ATO). A single type of these materials may be used alone, or two or more types may be mixed and used, as appropriate.

The cathode electrode 17 is an electrode that supplies electrons to the QD layer 15 when a voltage is applied to the cathode electrode 17. The cathode electrode 17 includes, for example, a material having a relatively small work function. Examples of the material include Al, silver (Ag), Ba, ytterbium (Yb), calcium (Ca), lithium (Li)—Al alloys, Mg—Al alloys, Mg—Ag alloys, Mg-indium (In) alloys, and Al-aluminum oxide (Al₂O₃) alloys.

Film formation of the anode electrode 12 and the cathode electrode 17 may be implemented using, for example, sputtering, film evaporation, film vapor deposition, vacuum vapor deposition, or physical vapor deposition (PVD).

The hole injection layer 13 is a layer that transports positive holes supplied from the anode electrode 12, to the hole transport layer 14. The hole injection layer 13 may be formed of an organic material or may be formed of an inorganic material. An example of the organic material is an electrically conductive polymer material. As the polymer material, for example, a composite (PEDOT:PSS) of poly(3,4-ethylenedioxythiophene) (PEDOT) and polystyrene sulfonic acid (PSS) can be used.

The hole transport layer 14 is a layer that transports positive holes supplied from the hole injection layer 13, to the QD layer 15. The hole transport layer 14 may be formed of an organic material or may be formed of an inorganic material. An example of the organic material is an electrically conductive polymer material. As the polymer material, for example, poly[(9,9-dioctylfluorenyl-2,7-diyl)-co-(4,4′-(N-(4-sec-butylphenyl) diphenylamine))] (TFB) and poly(N-vinylcarbazole) (PVK) can be used. A single type of these polymer materials may be used alone, or two or more types may be mixed and used, as appropriate. Of these polymer materials, when PVK is used, an even higher EQE can be obtained as demonstrated in the below-described Examples 2 and 3. Therefore, PVK is preferably used as the polymer material described above. In addition, the hole transport layer 14 is preferably formed so as to have a layer thickness within a range from 15 nm to 40 nm. This allows an even higher EQE to be obtained.

In the film formation of the hole injection layer 13 and the hole transport layer 14, for example, sputtering, vacuum vapor deposition, PVD, spin coating, or an ink-jet method may be used. Note that in a case where positive holes can be sufficiently supplied to the QD layer 15 only by the hole transport layer 14, the hole injection layer 13 need not be provided.

The electron transport layer 16 is a layer that transports electrons supplied from the cathode electrode 17, to the QD layer 15. The electron transport layer 16 may be formed of an organic material or may be formed of an inorganic material. When the electron transport layer 16 is formed of an inorganic material, the electron transport layer 16 may contain, as the inorganic material, a metal oxide containing at least one element selected from the group consisting of Zn, magnesium (Mg), titanium (Ti), silicon (Si), tin (Sn), tungsten (W), tantalum (Ta), barium (Ba), zirconium (Zr), aluminum (Al), yttrium (Y), and hafnium (Hf). Examples of such metal oxides include zinc oxide (ZnO) and zinc magnesium oxide (ZnMgO). A single type of these metal oxides may be used alone, or two or more types may be mixed and used, as appropriate. Also, nanoparticles may be used in the inorganic material. Of the abovementioned inorganic materials, the electron transport layer 16 preferably contains ZnMgO. By containing ZnMgO, an even higher external quantum efficiency (EQE) can be obtained as demonstrated in Example 2 described below. When the electron transport layer 16 is an inorganic material, spin coating or an ink-jet method, for example, can be used for film formation of the electron transport layer 16.

If the electron transport layer 16 is formed of an organic material, the electron transport layer 16 preferably contains, as the organic material, at least one type of compound selected from the group consisting of (i) 1,3,5-tris(1-phenyl-1H-benzimidazol-2-yl)benzene (TPBi), (ii) 3-(biphenyl-4-yl)-5-(4-tert-butylphenyl)-4-phenyl-4H-1,2,4-triazole (TAZ), (iii) bathophenanthroline (Bphen), and (iv) tris(2,4,6-trimethyl-3-(pyridin-3-yl)phenyl)borane (3TPYMB). If the electron transport layer 16 is formed of an organic material, film formation of the electron transport layer 16 may be implemented using vacuum vapor deposition. In addition, as in the case in which the material is an inorganic material, when the material is an organic material, spin coating or an ink-jet method may be used for film formation of the electron transport layer 16.

The QD layer 15 is a light-emitting layer (QD phosphor particle layer) provided between the anode electrode 12 and the cathode electrode 17 and containing the QD phosphor particles (quantum dots).

The QD phosphor particles emit the LB accompanied by recombination of the positive holes supplied from the anode electrode 12 and the electrons (free electrons) supplied from the cathode electrode 17. That is, the QD layer 15 emits light through electroluminescence (EL). More specifically, the QD layer 15 emits light through injection type EL.

Of the core and the shell covering the surface of the core, the QD phosphor particle includes at least a core.

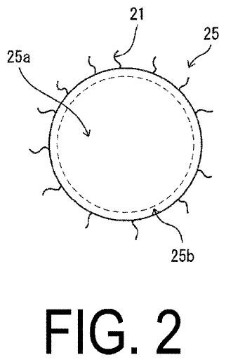

FIG. 2 is a schematic view illustrating an example of a QD phosphor particle 25 according to the present embodiment.

The QD phosphor particle 25 illustrated in FIG. 2 has a core-shell structure including a core 25a and a shell 25b covering the surface of the core 25a. Numerous ligands 21 are coordinated (adsorbed) on the surface of the QD phosphor particle 25 illustrated in FIG. 2. The ligand 21 is a surface-modifying group (organic ligand) that modifies the surface of the QD phosphor particle 25. The QD layer 15 formed by the solution method contains spherical QD phosphor particles 25 and ligands 21. By coordinating the ligands 21 on the surfaces of the QD phosphor particles 25, mutual aggregation of QD phosphor particles 25 can be suppressed, and thus target optical characteristics are easily exhibited.

However, as described above, the QD phosphor particle 25 may include only the core 25a. Even when the QD phosphor particle 25 is formed of only the core 25a, the QD phosphor particle 25 emits photoluminescence as LB in association with the recombination of positive holes and electrons. The shell 25b may be formed in a state of being solid-solved on the surface of the core 25a. In FIG. 2, the boundary between the core 25a and the shell 25b is indicated by a dotted line, and this indicates that the boundary between the core 25a and the shell 25b may or may not be confirmed by analysis.

The QD phosphor particles 25 according to the present embodiment are nanocrystals not containing cadmium (Cd). In the disclosure, the term “nanocrystal” indicates a nanoparticle having an approximate particle size from several nm to several tens of nm.

As the QD phosphor particle 25, a Cd-free QD phosphor particle having a core containing at least zinc (Zn) and selenium (Se) and not containing cadmium (Cd) is used. Note that in the disclosure, “not containing Cd” means that the QD phosphor particle 25 does not contain Cd at a mass ratio of 1/30 or greater in relation to Zn. Therefore, if the QD phosphor particles 25 have a core-shell structure as described above, “not containing Cd” means that the core 25a and the shell 25b both do not contain Cd at a mass ratio of 1/30 or greater in relation to Zn.

The QD phosphor particles 25 are preferably nanocrystals containing Zn and Se, Zn and Se and sulfur (S), Zn and Se and tellurium (Te), or Zn and Se and Te and S. Specifically, ZnSe-based, ZnSeS-based, ZnSeTe-based, or ZnSeTeS-based QD phosphor particles are used as the QD phosphor particles 25.

The core 25a is formed of, for example, ZnSe, ZnSeS, ZnSeTe, or ZnSeTeS. Among these exemplary materials, the material of the core 25a is preferably ZnSe or ZnSeS, and more preferably ZnSe.

The material of the shell 25b may be any material as long as the material does not contain Cd, and for example, the shell 25b may be formed of ZnS or ZnSeS. Among these exemplary materials, the material of the shell 25b is preferably ZnS.

According to the present embodiment, the fluorescence quantum yield (QY) can be further increased by covering the core 25a formed of a nanocrystal such as ZnSe, ZnSeS, ZnSeTe, or ZnSeTeS with a shell 25b such as ZnS or ZnSeS.

The fluorescence quantum yield of the QD phosphor particles 25 according to the present embodiment is not less than 5%. The fluorescence quantum yield is preferably 20% or greater, more preferably 50% or greater, and even more preferably 80% or greater. In this manner, the fluorescence quantum yield of the quantum dots can be increased in the present embodiment.

Note that the Zn and Se, the Zn and Se and S, the Zn and Se and Te, or the Zn and Se and Te and S included in QD phosphor particles 25 are the main components. The QD phosphor particles 25 may include elements besides these elements.

However, the QD phosphor particles 25 preferably do not contain Cd and do not contain phosphorus (P). Organic phosphorus compounds are expensive. Furthermore, organic phosphorus compounds are easily oxidized in air, and therefore a variety of problems are likely to occur such as unstable synthesis, an increase in costs, unstable fluorescence characteristics, and an increase in the complexity of the manufacturing process.

The QD phosphor particles 25 have fluorescence characteristics due to band-end light emission, and a quantum size effect occurs due to the particles being of a nano size.

A peak wavelength depends on subtle difference among the compositional ratios of the constituent elements of the QD phosphor particles 25, and the relationship between the particle size and the magnitude of wavelength dependence varies depending on the particle size region. However, regardless of whether the QD phosphor particles 25 have a core-shell structure, the particle size of the QD phosphor particles 25 is preferably in a range from 3 nm to 20 nm. Furthermore, the particle size of the QD phosphor particles 25 is more preferably within a range from 5 nm to 20 nm, regardless of whether the QD phosphor particles 25 have a core-shell structure. Moreover, the particle size of the QD phosphor particles 25 is more preferably 15 nm or less, and even more preferably 10 nm or less. In the present embodiment, the particle size of the QD phosphor particles 25 can be adjusted within the range described above, and a large number of QD phosphor particles 25 can be produced with a substantially uniform particle size.

Note that when the QD phosphor particles 25 have a core-shell structure, the particle size of the QD phosphor particles 25 indicates the particle size of the QD phosphor particles 25 in a state of being covered by the shell 25b (that is, the outermost particle size of the QD phosphor particles 25). According to the present embodiment, the QD phosphor particles 25 have a core-shell structure, and thus while the particle size is slightly larger than the structure of the core 25a alone, the particle size of the QD phosphor particles 25 can be maintained at 20 nm or less. In this manner, according to the present embodiment, QD phosphor particles 25 having a core-shell structure made uniform with a very small particle size can be obtained.

In the present embodiment, as described above, the particle size of the QD phosphor particles 25 can be reduced, and variations in the particle size of each QD phosphor particle 25 can be reduced, and thus QD phosphor particles 25 having uniform size can be obtained.

Accordingly, in the present embodiment, the fluorescence full-width at half-maximum of the QD phosphor particles 25 can be narrowed to 25 nm or less, and the formation of a high-color gamut can be improved. Note that in the disclosure, the “fluorescence full-width at half-maximum” is a full width at half maximum (FWHM), which indicates the spread of fluorescence wavelengths at half the intensity of a peak value of a fluorescence intensity in a fluorescent spectrum.

Additionally, the fluorescence full-width at half-maximum is preferably 23 nm or smaller, more preferably 20 nm or smaller, and even more preferably 15 nm or smaller. In the present embodiment, the fluorescence full-width at half-maximum can be narrowed in this manner, and thus the formation of a high color gamut can be improved.

In particular, the QD phosphor particles 25 according to the present embodiment are synthesized by synthesizing a copper chalcogenide as a precursor from a copper (Cu) raw material and an organic chalcogen compound (organic chalcogenide) as an Se raw material or a Te raw material, and then subjecting to a metal exchange of Cu of the copper chalcogenide with Zn. Note that an organic copper compound or an inorganic copper compound is used for the Cu raw material.

According to the present embodiment, synthesis can be safely implemented by synthesizing the QD phosphor particles 25 on the basis of an indirect synthesis reaction using these types of materials having relatively high stability (materials with relatively low reactivity), and as described above, QD phosphor particles 25 having a uniform size can be obtained. As a result, the fluorescence full-width at half-maximum can be narrowed, and a fluorescence full-width at half-maximum of 25 nm or less can be achieved as described above.

In addition, according to the present embodiment, the fluorescence lifetime of the QD phosphor particles 25 can be set to 50 ns or less. Note that in the disclosure, “fluorescence lifetime” indicates the “time until the initial intensity becomes 1/e (approximately 37%)”.

In addition, in the present embodiment, the fluorescence lifetime can be adjusted to 40 ns or less, and even 30 ns or less. In the present embodiment, the fluorescence lifetime can be shortened in this manner, but can also be extended to approximately 50 ns, and thus the fluorescence lifetime can be adjusted according to the usage application.

In the present embodiment, the fluorescence wavelength can be freely controlled to an approximate range from 410 nm to 470 nm. The fluorescent peak wavelength of the QD phosphor particles 25 is within a range from 410 nm to 470 nm. According to the present embodiment, the fluorescence wavelength can be controlled by adjusting the particle size and composition of the QD phosphor particles 25. The QD phosphor particles 25 are, for example, ZnSe-based or ZnSeS-based solid solution bodies in which a chalcogen element is used in addition to Zn. In this case, the fluorescence wavelength can be preferably set in a range from 430 nm to 470 nm, and more preferably in a range from 450 nm to 470 nm. Furthermore, in the ZnSeTe-based or ZnSeTeS-based QD phosphor particles 25, the fluorescence wavelength can be set to within a range from 450 nm to 470 nm. In this manner, the fluorescence wavelength of the QD phosphor particles 25 can be controlled to blue in the present embodiment.

In the present embodiment, even when the QD phosphor particles 25 have a core-shell structure, the fluorescence wavelength can be freely controlled to an approximate range from 410 nm to 470 nm. That is, according to the present embodiment, the fluorescence wavelength can be controlled to blue even when the QD phosphor particles 25 have a core-shell structure.

In addition, in the present embodiment, even when the QD phosphor particles 25 have a core-shell structure, the fluorescence full-width at half-maximum, the fluorescence quantum yield, and the fluorescence lifetime described above can be obtained. In particular, according to the present embodiment, the fluorescence lifetime can be further shortened by adopting a core-shell structure for the QD phosphor particles 25 in comparison to a core 5a alone having the same composition and particle size. Note that the above-described preferred ranges of the fluorescence full-width at half-maximum, fluorescence quantum yield, and fluorescence lifetime can be applied even when the QD phosphor particles 25 have a core-shell structure.

Furthermore, in comparison to a case of the core 25a alone, the fluorescent peak wavelength can be shortened or lengthened by covering the core 25a with the shell 25b. For example, when the particle size of the core 25a is small, the fluorescent peak wavelength tends to be lengthened by covering the core 25a with the shell 25b. On the other hand, when the particle size of the core 25a is large, the fluorescent peak wavelength tends to be shortened by covering the core 25a with the shell 25b. Note that the magnitude of change in the wavelength varies depending on the conditions of covering with the shell 25b.

The thickness (shell thickness) of the shell 25b is one of the most important factors determining the efficiency and reliability of the electroluminescent element 1 (QLED). In order to obtain better light emission performance, it is desirable that the QD phosphor particles 25 have a core-shell structure. When the shell thickness is too thick, the fluorescence quantum yield (QY) decreases.

When the QD phosphor particles 25 have a core-shell structure, as described above, the outermost particle size of the QD phosphor particle 25 including the shell 25b is from 3 nm to 20 nm, and is more preferably from 5 nm to 20 nm.

According to the disclosure, when a case is included in which the QD phosphor particles 25 are formed of only the core 25a, a fluorescence wavelength of 50 ns or less and a high fluorescence quantum yield (QY) can be obtained by setting the thickness of the shell 25b to less than 10 nm (that is, from 0 to less than 10 nm). The external quantum efficiency (%) is expressed by (carrier balancing)×(generation efficiency of luminescent excitons)×(fluorescence quantum yield)×(light extraction efficiency) and is proportional to the fluorescence quantum yield. Therefore, an electroluminescent element 1 that can realize a high external quantum efficiency (EQE) can be provided by setting the thickness of the shell 25b to less than 10 nm.

Note that when the QD phosphor particles 25 have a core-shell structure, the thickness of the shell 25b is more preferably 0.3 nm or greater, even more preferably 0.5 nm or greater, yet even more preferably 0.8 nm or greater, and even further preferably 1.0 nm or greater. Furthermore, the thickness of the shell 25b is more preferably 3.3 nm or less, even more preferably 2.8 nm or less, and yet even more preferably 1.7 nm or less.

For example, the fluorescence lifetime can be set to 15 ns or less, and a fluorescence quantum yield (QY) of 20% or greater can be obtained by setting the thickness of the shell 25b to a range from 0.3 nm to 3.3 nm. Therefore, an electroluminescent element 1 that can emit light having a short fluorescence lifetime and high brightness and can realize a higher external quantum efficiency (EQE) can be provided by setting the thickness of the shell 25b to a range from 0.3 nm to 3.3 nm.

Furthermore, the fluorescence lifetime can be set to 15 ns or less, and a higher fluorescence quantum yield (QY) of 30% or greater can be obtained by setting the thickness of the shell 25b to a range from 0.5 nm to 3.3 nm. Therefore, an electroluminescent element 1 that can emit light having a short fluorescence lifetime and high brightness and can realize a higher external quantum efficiency (EQE) can be provided by setting the thickness of the shell 25b to a range from 0.5 nm to 3.3 nm.

Furthermore, the fluorescence lifetime can be set to 15 ns or less, and a higher fluorescence quantum yield (QY) of 40% or greater can be obtained by setting the thickness of the shell 25b to a range from 0.8 nm to 3.3 nm. Accordingly, an electroluminescent element 1 that can emit light having a short fluorescence lifetime and high brightness and can realize a higher external quantum efficiency (EQE) can be provided by setting the thickness of the shell 25b to a range from 0.8 nm to 3.3 nm.

Furthermore, the fluorescence lifetime can be set to 15 ns or less, and a higher fluorescence quantum yield (QY) of 50% or greater can be obtained by setting the thickness of the shell 25b to a range from 1 nm to 2.8 nm. Therefore, an electroluminescent element 1 that can emit light having a short fluorescence lifetime and high brightness and can realize a higher external quantum efficiency (EQE) can be provided by setting the thickness of the shell 25b to a range from 1.0 nm to 2.8 nm.

Furthermore, the fluorescence lifetime can be set to 10 ns or less, and a higher fluorescence quantum yield (QY) of 40% or greater can be obtained by setting the thickness of the shell 25b to a range from 0.8 nm to 1.7 nm. Accordingly, an electroluminescent element 1 that can emit light having a short fluorescence lifetime and high brightness and can realize a higher external quantum efficiency (EQE) can be provided by setting the thickness of the shell 25b to a range from 0.8 nm to 1.7 nm.

Furthermore, the fluorescence lifetime can be set to 10 ns or less, and a higher fluorescence quantum yield (QY) of 50% or greater can be obtained by setting the thickness of the shell 25b to a range from 1 nm to 1.7 nm. Therefore, an electroluminescent element 1 that can emit light having a short fluorescence lifetime and high brightness and can realize a higher external quantum efficiency (EQE) can be provided by setting the thickness of the shell 25b to a range from 1.0 nm to 1.7 nm.

Note that with the core-shell type QD phosphor particles 25, the wavelength of the light emitted by the QD phosphor particles 25 is proportional to the particle size of the core 25a and does not depend on the particle size of the shell 25b (the outermost particle size of the QD phosphor particles 25). Here, the core size is calculated by (core size)=(outermost particle size)−(shell thickness)×2 and is not particularly limited as long as blue light is emitted. However, the core size is preferably in the range of, for example, from 0.5 nm to 15 nm.

Note that as illustrated in FIG. 2, numerous ligands 21 are preferably coordinated on the surface of the QD phosphor particle 25. Through this, aggregation of the QD phosphor particles 25 can be suppressed, and the intended optical characteristics are expressed. Furthermore, the addition of amine-based or thiol-based ligands 21 can greatly improve the stability of the light-emission characteristics of the QD phosphor particles 25. The ligand 21 that can be used in the reaction is not particularly limited, and examples of the ligand 21 include amine-based (aliphatic primary amine-based), fatty acid-based, thiol-based (sulfur-based), phosphine-based (phosphorus-based), and phosphine oxide-based ligands.

Examples of aliphatic primary amine-based ligands 21 include oleylamine (C₁₈H₃₅NH₂), stearyl (octadecyl) amine (C₁₈H₃₇NH₂), dodecyl (lauryl) amine (C₁₂H₂₅NH₂), decylamine (C₁₀H₂₁NH₂), and octylamine (C₈H₁₇NH₂).

Examples of the fatty acid-based ligands 21 include oleic acid (C₁₇H₃₃COOH), stearic acid (C₁₇H₃₅COOH), palmitic acid (C₁₈H₃₁COOH), myristic acid (C₁₃H₂₇COOH), lauric (dodecanoic) acid (C₁₁H₂₃COOH), decanoic acid (C₉H₁₉COOH), and octanoic acid (C₇H₁₅COOH).

Examples of the thiol-based ligands 21 include octadecanethiol (C₁₈H₃₇SH), hexadecanethiol (C₁₆H₃₃SH), tetradecanethiol (C₁₄H₂₉SH), dodecanethiol (C₁₂H₂₅SH), decanethiol (C₁₀H₂₁SH), and octanethiol (C₈H₁₇SH).

Examples of the phosphine-based ligands 21 include trioctylphosphine ((C₈H₁₇)₃P), triphenylphosphine ((C₆H₅)₃P), and tributyl phosphine ((C₄H₉)₃P).

Examples of the phosphine oxide-based ligands 21 include trioctylphosphine oxide ((C₈H₁₇)₃P═O), triphenylphosphine oxide ((C₆H₅)₃P═O), and tributyl phosphine oxide ((C₄H₉)₃P═O).

The QD layer 15 is preferably formed such that the layer thickness is from 15 nm to 35 nm. When the layer thickness is set to such a range, high EQE can be obtained as demonstrated in Example 1 described below.

In the electroluminescent element 1, a forward voltage is applied between the anode electrode 12 and the cathode electrode 17. In other words, the anode electrode 12 is set to a higher potential than the cathode electrode 17. Through this, (i) electrons can be supplied from the cathode electrode 17 to the QD layer 15, and (ii) positive holes can be supplied from the anode electrode 12 to the QD layer 15. As a result, the QD layer 15 can generate the LB in association with the recombination of the positive holes and the electrons. The above-described application of voltage may be controlled by a thin film transistor (TFT) (not illustrated). As an example, a TFT layer including a plurality of TFTs may be formed in the substrate 11.

Note that the electroluminescent element 1 may include, as a function layer, a hole blocking layer (HBL) that suppresses the transport of positive holes. The hole blocking layer is provided between the anode electrode 12 and the QD layer 15. By providing the hole blocking layer, the balance of the carriers (i.e., positive holes and electrons) supplied to the QD layer 15 can be adjusted.

In addition, the electroluminescent element 1 may include, as a function layer, an electron blocking layer (EBL) that suppresses the transport of electrons. The electron blocking layer is provided between the QD layer 15 and the cathode electrode 17. By providing the electron blocking layer, the balance of the carriers (i.e., positive holes and electrons) supplied to the QD layer 15 can also be adjusted.

The electroluminescent element 1 may be sealed after film formation as far as the cathode electrode 17 has been completed. For example, a glass or a plastic can be used as a sealing member. The sealing member has, for example, a concave shape so that a layered body from the substrate 11 to the cathode electrode 17 can be sealed. For example, after a sealing adhesive (e.g., an epoxy-based adhesive) is applied between the sealing member and the substrate 11, sealing is performed in a nitrogen (N₂) atmosphere, and thereby the electroluminescent element 1 is manufactured.

### Application to Display Device

As described above, the electroluminescent element 1 may be adopted, for example, as a blue light source of a display device. The light source including the electroluminescent element 1 may include an electroluminescent element as a red light source and an electroluminescent element as a green light source. In this case, the light source functions as, for example, a light source for lighting an R pixel, a G pixel, and a B pixel, as indicated in a below-described second embodiment. The display device including this light source can express an image by a plurality of pixels including the R pixel, the G pixel, and the B pixel.

For example, the R pixel, the G pixel, and the B pixel are each formed by using an ink-jet method or the like for separate application on the substrate 11 provided with a bank. For example, indium phosphide (InP) is suitably used as the red QD phosphor particles and the green QD phosphor particles used for the R pixel and G pixel respectively, as long as the materials are limited to non-Cd-based materials. When InP is used, the fluorescence full-width at half-maximum can be made relatively narrow, and high luminous efficiency can be obtained.

Film formation of the electron transport layer 16 may be implemented with a plurality of pixel units or may be implemented in common for the plurality of pixels, provided that the display device can light up the R pixel, G pixel, and B pixel individually.

### Method for Manufacturing Electroluminescent Element

Next, an example of a method for manufacturing the electroluminescent element 1 will be described. The electroluminescent element 1 is manufactured, for example, by performing film formation of the anode electrode 12, the hole injection layer 13, the hole transport layer 14, the QD layer 15, the electron transport layer 16, and the cathode electrode 17 on or above the substrate 11 in this order.

Specifically, for example, the anode electrode 12 is formed on the substrate 11 by sputtering (anode electrode formation step). Next, after a solution containing, for example, PEDOT:PSS has been applied to the anode electrode 12 by spin coating, the solvent is volatilized by baking to form the hole injection layer 13 (hole injection layer formation step). Next, after a solution containing, for example, TFB is applied to the hole injection layer 13 by spin coating, the solvent is volatilized by baking to form the hole transport layer 14 (hole transport layer formation step). Next, the QD layer 15 is formed on the hole transport layer 14 using a solution method. Specifically, after a solution (liquid composition) in which the QD phosphor particles 25 are dispersed has been applied to the hole transport layer 14 by spin coating, the solvent is volatilized by baking to form the QD layer 15 (light-emitting layer formation step). Next, after a solution containing, for example, nanoparticles of ZnO has been applied to the QD layer 15 by spin coating, a solvent is volatilized by baking to form the electron transport layer 16. Next, the cathode electrode 17 is formed on the electron transport layer 16 by vacuum vapor deposition (electron transport layer formation step).

Note that the QD phosphor particles 25 contained in the QD layer 15 are synthesized by synthesizing a copper chalcogenide as a precursor from an organic copper compound or an inorganic copper compound and an organic chalcogen compound and then using the copper chalcogenide (quantum dot synthesis step). In other words, in the light-emitting layer formation step, the QD layer 15 containing the QD phosphor particles 25 synthesized in this manner is formed. The quantum dot synthesis step (also referred to as a QD phosphor particle synthesis step) will be described later.

Note that as described above, in the light-emitting layer formation step, the QD layer 15 is formed such that the layer thickness thereof is from 15 nm to 35 nm.

Also, as described above, in the hole transport layer formation step, the hole transport layer 14 is formed such that the layer thickness thereof is from 15 nm to 40 nm.

Note that after the film formation of the cathode electrode 17, the substrate 11 and the layered body (the anode electrode 12 to the cathode electrode 17) formed on the substrate 11 may be sealed with a sealing member in an N₂ atmosphere.

### Method for Synthesizing QD Phosphor Particles 25

Next, an example of a method for synthesizing the QD phosphor particles 25 (QD phosphor particle synthesis step) will be described.

In the present embodiment, a copper chalcogenide is synthesized as the precursor from a Cu raw material (an organic copper compound or an inorganic copper compound) and an organic chalcogen compound as an Se raw material or Te raw material. Preferable examples of the copper chalcogenide (precursor) include Cu₂Se, Cu₂SeS, Cu₂SeTe, and Cu₂SeTeS.

The organic copper compound (organic copper reagent) used as the Cu raw material is not particularly limited, and examples thereof include acetates and fatty acid salts. Furthermore, the inorganic copper compound (inorganic copper reagent) used as the Cu raw material is also not particularly limited, and examples thereof include halides (copper halides).

More specifically, examples of the acetates include copper (I) acetate (Cu(OAc)) and copper (II) acetate (Cu(OAc)₂).

Examples of the fatty acid salts include copper (II) stearate (Cu(OC(═O)C₁₇H₃₅)₂), copper oleate (Cu(OC(═O)C₁₇H₃₃)₂), copper myristate (Cu(OC(═O)C₁₃H₂₇)₂), copper dodecanoate (Cu(OC(═O)C₁₁H₂₃)₂), and copper acetylacetonate (Cu(acac)₂).

Both monovalent and divalent compounds can be used as the halide. Examples of the halide include copper(I) chloride (CuCl), copper(II) chloride (CuCl₂), copper(I) bromide (CuBr), copper(II) bromide (CuBr₂), copper(I) iodide (CuI), and copper(II) iodide (CuI₂).

In the present embodiment, an organic selenium compound (organic chalcogen compound) is used as a raw material of Se. The organic selenium compound (organic chalcogen compound) is not particularly limited, and for example, trioctylphosphine selenide ((C₈H₁₇)₃P═Se) obtained by dissolving Se in trioctylphosphine, and tributylphosphine selenide ((C₄H₉)₃P═Se) obtained by dissolving Se in tributylphosphine can be used. Also, other examples of the organic selenium compound (organic chalcogen compound) that can be used include a solution (Se-ODE) in which Se is dissolved at a high temperature in a high boiling point solvent, which is a long chain hydrocarbon such as octadecene, and a solution (Se-DDT/OLAm) in which Se is dissolved in a mixture of oleylamine and dodecanethiol.

In the present embodiment, an organic tellurium compound (organic chalcogen compound) is used as the Te raw material. The organic tellurium compound (organic chalcogen compound) is not particularly limited, and for example, trioctylphosphine telluride ((C₈H₁₇)₃P═Te) obtained by dissolving Te in trioctylphosphine, and tributylphosphine telluride ((C₄H₉)₃P═Te) obtained by dissolving Te in tributylphosphine can be used. Also, as the organic tellurium compound (organic chalcogen compound), a dialkyl ditelluride (R₂Te₂; where R denotes a C₁-C₆ alkyl group), such as diphenyl ditelluride ((C₆H₅)₂Te₂) can be used.

In the synthesis of the copper chalcogenide, first, an organic copper compound or an inorganic copper compound, and an organic chalcogen compound are mixed and dissolved in a solvent.

Examples of the solvent include saturated or unsaturated hydrocarbons having a high boiling point. Examples of high boiling point saturated hydrocarbons that can be used include n-dodecane, n-hexadecane, and n-octadecane. An example of a high boiling point unsaturated hydrocarbon that can be used is octadecene. Note that, for example, an aromatic solvent having a high boiling point, and an ester-based solvent having a high boiling point may also be used as the solvent. For example, t-butyl benzene can be used as an aromatic solvent having a high boiling point. Examples of high boiling point ester-based solvents that can be used include butyl butyrate (C₄H₉COOC₄H₉) and benzyl butyrate (C₆H₅CH₂COOC₄H₉). However, aliphatic amine-based compounds, fatty acid-based compounds, aliphatic phosphorus-based compounds, or mixtures thereof can also be used as the solvent.

Next, the reaction temperature is set to within a range from 140° C. to 250° C., and the copper chalcogenide (precursor) is synthesized. Note that the reaction temperature is preferably a lower temperature within a range from 140° C. to 220° C., and more preferably an even lower temperature within a range from 140° C. to 200° C. In this manner, according to the present embodiment, the copper chalcogenide can be synthesized at a low temperature, and therefore the copper chalcogenide can be safely synthesized. In addition, since the reaction during synthesis is gentle, the reaction is easier to control.

Note that in the present embodiment, the reaction method is not particularly limited, but it is important to synthesize Cu₂Se, Cu₂SeS, Cu₂SeTe, and Cu₂SeTeS having uniform particle sizes in order to obtain the QD phosphor particles 25 having a narrow fluorescence full-width at half-maximum.

Also, the particle size of the copper chalcogenide (precursor) such as Cu₂Se, Cu₂SeS, Cu₂SeTe, and Cu₂SeTeS is preferably 20 nm or less, more preferably 15 nm or less, and even more preferably 10 nm or less. Wavelength control of QD phosphor particles 25 such as ZnSe-based, ZnSeS-based, ZnSeTe-based, and ZnSeTeS-based QD phosphor particles is enabled depending on the composition and particle size of this copper chalcogenide. Therefore, it is important to appropriately control the particle size.

It is also important to solid-solve S in the core in order to obtain QD phosphor particles 25 with a narrower fluorescence full-width at half-maximum as the core. For this reason, thiol is preferably added in the synthesis of, for example, Cu₂Se or Cu₂SeTe as the precursor. Also, the above-described Se-DDT/OLAm is more preferably used as the Se raw material in order to obtain the QD phosphor particles 25 having a narrower fluorescence full-width at half-maximum.

While the thiol is not particularly limited, examples of thiols that can be used include octadecanethiol (C₁₈H₃₇SH), hexadecanethiol (C₁₆H₃₃SH), tetradecanethiol (C₁₄H₂₉SH), dodecanethiol (C₁₂H₂₅SH), decanethiol (C₁₀H₂₁SH), and octanethiol (C₈H₁₇SH).

Next, an organic zinc compound or an inorganic zinc compound is prepared as a Zn raw material of ZnSe, ZnSeS, ZnSeTe or ZnSeTeS. The organic zinc compound or the inorganic zinc compound is a raw material that is stable even in air and easy to handle. The organic zinc compound or the inorganic zinc compound is not particularly limited, but a zinc compound with high ionic properties is preferably used in order to efficiently carry out a metal exchange reaction. Examples of the organic zinc compound include acetates, nitrates and fatty acid salts. Examples of the inorganic zinc compound include halides (zinc halides).

An example of the acetate that can be used is zinc acetate (Zn(OAc)₂). An example of the nitrate that can be used is zinc nitrate (Zn(NO₃)₂).

More specifically, examples of fatty acid salts that can be used include zinc stearate (Zn(OC(═O)C₁₇H₃₅)₂), zinc oleate (Zn(OC(═O)C₁₇H₃₃)₂), zinc palmitate (Zn(OC(═O)C₁₈H₃₁)₂), zinc myristate (Zn(OC(═O)C₁₃H₂₇)₂), zinc dodecanoate (Zn(OC(═O)C₁₁H₂₃)₂), and zinc acetylacetonate (Zn(acac)₂).

Note that the organic zinc compound may be a zinc carbamate. Examples of zinc carbamates that can be used include zinc diethyldithiocarbamate (Zn(SC(═S)N(C₂H₅)₂)₂), zinc dimethyldithiocarbamate (Zn(SC(═S)N(CH₃)₂)₂), and zinc dibutyldithiocarbamate (Zn(SC(═S)N(C₄H₉)₂)₂).

Examples of halides that can be used include zinc chloride (ZnCl₂), zinc bromide (ZnBr₂), and zinc iodide (ZnI₂).

Subsequently, the above-described organic zinc compound or inorganic zinc compound is added to the reaction solution in which the copper chalcogenide (precursor) was synthesized. This results in a metal exchange reaction between Cu of the copper chalcogenide and Zn. The metal exchange reaction is preferably carried out at a temperature from 150° C. to 300° C. Further, the metal exchange reaction is more preferably carried out at a lower temperature in a range from 150° C. to 280° C., and is even more preferably carried out at a temperature in a range from 150° C. to 250° C. In this manner, in the present embodiment, the metal exchange reaction can be carried out at a lower temperature, and therefore the safety of the metal exchange reaction can be increased. Furthermore, the metal exchange reaction is more easily controlled.

In the present embodiment, preferably, the metal exchange reaction between Cu and Zn proceeds quantitatively, and the nanocrystals do not contain the Cu of the precursor. This is because when the Cu of the copper chalcogenide remains in the nanocrystals, the Cu serves as a dopant, light is emitted by another light emission mechanism, and the fluorescence full-width at half-maximum could be widened as a result. The residual amount of this Cu is preferably 100 ppm or less, more preferably 50 ppm or less, and ideally 10 ppm or less, in relation to the Zn.

ZnSe-based QD phosphor particles 25 synthesized by a cation exchange method tend to have a higher residual amount of Cu than ZnSe-based QD phosphor particles 25 synthesized by a direct method. However, even though Cu is included in a range from 1 to 10 ppm in relation to Zn, excellent light-emission characteristics can be obtained. Note that the residual amount of Cu enables the determination as to whether the QD phosphor particles 25 is synthesized by the cation exchange method. That is, synthesis by the cation exchange method enables control of the particle size with the copper chalcogenide, and also enables the synthesis of QD phosphor particles 25 that are naturally difficult to react. Therefore, the residual amount of Cu can be used to determine whether the cation exchange method was used.

Also, in the present embodiment, a compound having an auxiliary role of releasing the metal of the copper chalcogenide into the reaction solution by coordination, chelating, or the like is required when metal exchange is carried out.

An example of the compound having the above-described role is a ligand (surface modifier) capable of forming a complex with Cu. As this ligand, a ligand similar to the ligands given as examples above can be used. Preferable examples of the ligand include the above-described phosphine-based (phosphorus-based) ligands, amine-based ligands, and thiol-based (sulfur-based) ligands. Among these, in consideration of the magnitude of the reaction efficiency, a phosphine-based (phosphorus-based) ligand is more preferable. Through the use of such ligands, the metal exchange between Cu and Zn is appropriately implemented, and QD phosphor particles having a narrow fluorescence full-width at half-maximum and based on Zn and Se can be manufactured. In the present embodiment, the QD phosphor particles 25 can be more easily mass-produced by the above-described cation exchange method than the direct synthesis method.

That is, in the direct synthesis method, for example, an organic zinc compound such as diethylzinc (Et₂Zn) is used to increase the reactivity of Zn raw materials. However, diethylzinc is highly reactive and ignites in air, and therefore raw material handling and storage are difficult. For example, the material needs to handle in an inert gas stream. A reaction using diethylzinc also carries risks such as exotherm and ignition, and therefore diethylzinc is not suited for mass production. Likewise, reactions in which, for example, hydrogen selenide (H₂Se) is used to increase the reactivity of the Se raw material are also not suited for mass production from the perspectives of toxicity and safety.

In addition, in reaction systems using a Zn raw material and a Se raw material with high reactivity as described above, ZnSe is produced, but particle production is not controlled, and as a result, the fluorescence full-width at half-maximum of the produced ZnSe becomes wider.

In contrast, as described above, in the present embodiment, the copper chalcogenide is synthesized as the precursor from an organic copper compound or an inorganic copper compound and an organic chalcogen compound. Furthermore, the QD phosphor particles 25 are synthesized by implementing metal exchange using the precursor. Thus, in the present embodiment, the QD phosphor particles 25 are synthesized through the synthesis of the precursor, and the QD phosphor particles 25 are not synthesized directly from the raw materials. According to the present embodiment, through this type of indirect synthesis, it is not necessary to use dangerous reagents that are highly reactive and difficult to handle, and ZnSe-based QD phosphor particles 25 having a narrow fluorescence full-width at half-maximum can be safely and stably synthesized.

Furthermore, in the present embodiment, it is also not always necessary to isolate and purify the precursor. Thus, for example, the desired QD phosphor particles 25 can be obtained by implementing metal exchange between Cu and Zn in one pot. However, the copper chalcogenide, which is the precursor, may also be isolated and purified prior to synthesis of the QD phosphor particles 25, and then used.

The QD phosphor particles 25 synthesized by the above-described technique can exhibit predetermined fluorescence characteristics without the implementation of various treatments such as cleaning, isolation and purification, a covering treatment, and ligand exchange.

However, as described above, the fluorescence quantum yield can be further increased by covering the core 25a made of a nanocrystal such as ZnSe, ZnSeS, ZnSeTe, or ZnSeTeS, with a shell 25b made of ZnS, ZnSeS, or the like. Furthermore, adopting the core-shell structure allows the fluorescence lifetime to be shortened in comparison to prior to covering with a shell.

In addition, as described above, in comparison to a case of the core 25a alone, the fluorescent peak wavelength can be shortened or lengthened by adopting a core-shell structure.

Also, by adding, to the core 25a made of nanocrystals such as ZnSe, ZnSeS, ZnSeTe, or ZnSeTeS obtained by the cation exchange method, the same raw materials of ZnSe, ZnSeS, ZnSeTe, or ZnSeTeS, a core 25a of QD phosphor particles 25 changed to any particle size while maintaining a uniform particle size can be obtained. Therefore, the wavelength is easily controlled to a range from 410 nm to 470 nm while maintaining the fluorescence full-width at half-maximum at 25 nm or less.

According to the present embodiment, the core-shell structure (core/shell structure) can be formed at the stage of synthesizing the precursor. For example, as the precursor, a precursor (copper chalcogenide) having a core/shell structure of Cu₂Se/Cu₂S can be synthesized by first synthesizing Cu₂Se, and then continuously adding the S raw material. Subsequently, QD phosphor particles 25 having a core/shell structure of ZnSe/ZnS can be synthesized by carrying out metal exchange between Cu and Zn.

In the present embodiment, the S-based material used in the shell 25b is not particularly limited. Examples of the S-based material that can be typically used include thiols.

Examples of the abovementioned thiols that can be used include octadecanethiol (C₁₈H₃₇SH), hexadecanethiol (C₁₆H₃₃SH), tetradecanethiol (C₁₄H₂₉SH), dodecanethiol (C₁₂H₂₅SH), decanethiol (C₁₀H₁₂SH), octanethiol (C₈H₁₇SH), benzenethiol (C₆H₅SH), a solution (S-TOP) obtained by dissolving sulfur in a high boiling point solvent, which is a long-chain phosphine-based hydrocarbon, such as a trioctylphosphine, a solution (S-ODE) obtained by dissolving sulfur in a high boiling point solvent, which is a long-chain hydrocarbon such as octadecene, and a solution (S-DDT/OLAm) obtained by dissolving sulfur in a mixture of oleylamine and dodecanethiol.

The reactivity differs depending on the S raw material that is used, and as a result, the covering thickness of the shell 25b (for example, ZnS) can be differed. The thiol system is proportional to the degradation rate thereof, and the reactivity of S-TOP or S-ODE varies in proportion to the stability thereof. Through this, the covering thickness of the shell 25b and the final fluorescence quantum yield can be controlled by also using a proper S raw material.

In the present embodiment, examples of the Zn raw material that can be used in the core-shell structure include a Zn raw material such as an organic zinc compound or an inorganic zinc compound described above.

Furthermore, with regard to the solvent used during covering with the shell 25b, as the amount of an amine-based solvent is reduced, it becomes easier to form the covering of the shell 25b, and more favorable light-emission characteristics can be obtained. In addition, the light-emission characteristics of the shell 25b after covering differ depending on the ratio of the amine-based solvent and the carboxylic acid-based solvent or phosphine-based solvent.

Moreover, the QD phosphor particles 25 synthesized by the manufacturing method of the present embodiment are aggregated by adding a polar solvent such as methanol, ethanol, or acetone, and the QD phosphor particles 25 and the unreacted raw materials can thereby be separated and recovered. The recovered QD phosphor particles 25 are again dispersed by adding, once again, a solvent such as toluene or hexane thereto. By adding a solvent that becomes the ligands 21 to the re-dispersed solution, the light-emission characteristics and stability of those light-emission characteristics can be further improved. The change in light-emission characteristics caused by the addition of the ligand 21 differs greatly depending on the presence or absence of a covering operation of the shell 25b. The QD phosphor particles 25 that are covered by the shell 25b can improve particularly fluorescence stability by adding a thiol-based ligand 21.

### EXAMPLES

Next, effects of the electroluminescent element 10 according to the present embodiment will be described through examples and comparative examples. However, the electroluminescent element 1 according to the present embodiment is not limited to the following examples.

First, synthesis examples of the QD phosphor particles 25 according to the present embodiment will be described.

Note that in the following synthesis examples, as the oleylamine, “Farmin” available from Kao Corporation was used. Also, “Lunac O-V” available from Kao Corporation was used as the oleic acid. “Thiokalcol 20” available from Kao Corporation was used as the dodecanethiol (Se-DDT). Furthermore, an anhydrous copper acetate available from Wako Pure Chemical Industries, Ltd. was used as the anhydrous copper acetate. An octadecene (ODE) available from Idemitsu Kosan Co., Ltd. was used as the octadecene. A trioctylphosphine available from Hokko Chemical Industry Co., Ltd. was used as the trioctylphosphine. An anhydrous zinc acetate available from Kishida Chemical Co., Ltd. was used as the anhydrous zinc acetate.

### Synthesis Example 1 of QD Phosphor Particles 25

A 300 mL reaction vessel was charged with 543 mg of anhydrous copper acetate (Cu(OAc)₂) as a Cu raw material (organic copper compound), 28.5 mL of oleylamine (OLAm) as a ligand, and 46.5 mL of octadecene (ODE) as a solvent. The raw materials in the reaction vessel were then heated and dissolved at 150° C. for 20 minutes in an inert gas (N₂) atmosphere while being stirred, and a solution was thereby obtained.

Next, 8.4 mL of an Se-DDT/OLAm solution (0.285 M) was added as an organic chalcogen compound to the solution, and the resulting mixture was heated at 150° C. for 10 minutes while being stirred. The reaction solution (Cu₂Se reaction liquid, copper chalcogenide) thereby obtained was cooled to room temperature.

Subsequently, 4.092 g of anhydrous zinc acetate (Zn(OAc)₂) as an organic zinc compound, 60 mL of trioctylphosphine (TOP) as a solvent, and 2.4 mL of oleylamine (OLAm) as a ligand were added to the Cu₂Se reaction liquid, and the resulting mixture was heated at 180° C. for 30 minutes in an inert gas (N₂) atmosphere while being stirred. As a result, a metal exchange reaction occurred between Cu of the copper chalcogenide and Zn. The resulting reaction solution (ZnSe solution) was cooled to room temperature.

Next, ethanol was added to the reaction solution cooled to room temperature to generate a precipitate, and the reaction solution was centrifuged to recover the precipitate. Next, 72 mL of octadecene (ODE) was added as a solvent (dispersion medium) to the recovered precipitate, and the precipitate was dispersed, and thereby a ZnSe-ODE dispersion was obtained.

Subsequently, 4.092 g of anhydrous zinc acetate (Zn(OAc)₂) as an organic zinc compound, 30 mL of trioctylphosphine (TOP) as a solvent (dispersion medium), and 3 mL of oleylamine (OLAm) and 36 mL of oleic acid as ligands were added to 72 mL of this ZnSe-ODE dispersion, and the mixture was heated at 280° C. for 30 minutes in an inert gas (N₂) atmosphere while being stirred. The resulting reaction solution (ZnSe dispersion) was cooled to room temperature.

The fluorescence wavelength and the fluorescence full-width at half-maximum of ZnSe in this reaction solution (ZnSe dispersion) were measured using a fluorescence spectrometer. The F-2700 fluorescence spectrometer available from JASCO Corporation was used as the fluorescence spectrometer. The measurement results indicated optical characteristics including a fluorescence wavelength of approximately 430.5 nm and a fluorescence full-width at half-maximum of approximately 15 nm.

Furthermore, the fluorescence quantum yield of ZnSe in the reaction solution (ZnSe dispersion) was measured using a quantum efficiency measurement system. The QE-1100 quantum efficiency measurement system available from Otsuka Electronics Co. Ltd. was used as the quantum efficiency measurement system. The measurement results showed that the fluorescence quantum yield was approximately 30%. The fluorescence lifetime of ZnSe in the reaction solution (ZnSe dispersion) was also measured and was found to be 48 ns. Note that the C11367 fluorescence lifetime measurement device available from Hamamatsu Photonics KK was used to measure the fluorescence lifetime.

Furthermore, the particle size of ZnSe in the reaction solution (ZnSe dispersion) was measured using a scanning electron microscope (SEM). Furthermore, X-ray diffraction spectrum of ZnSe in the reaction solution (ZnSe dispersion) was measured using an X-ray diffraction (XRD) device.

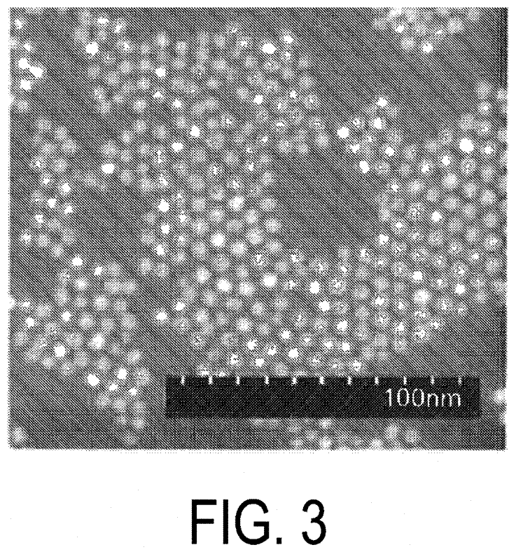

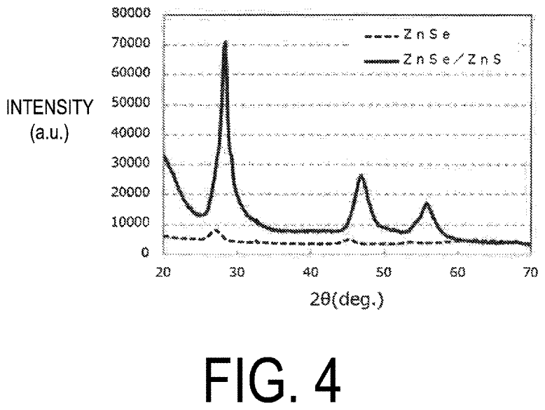

FIG. 3 is an image of a scanning electron micrograph of ZnSe obtained in the present embodiment. In addition, the spectrum indicated by the dotted line in FIG. 4 is the X-ray diffraction spectrum of the ZnSe described above. Note that the SU9000 scanning electron microscope available from Hitachi, Ltd. was used as the scanning electron microscope. Furthermore, the D2 PHASER X-ray diffraction device available from Bruker Corporation was used as the X-ray diffraction device.

From the results illustrated in FIG. 3, the particle size of the ZnSe was approximately 5 nm. Note that this particle size was calculated as an average value of observed samples in particle observation using the scanning electron microscope described above. Additionally, from the results indicated by the dotted line in FIG. 4, it was found that the ZnSe crystal was a cubic crystal, and the peak position thereof was consistent with the crystal peak position of ZnSe.

Next, 47 mL of the reaction solution (ZnSe dispersion) was collected, ethanol was added thereto to generate a precipitate, and the mixture was centrifuged to recover the precipitate. Next, 35 mL of octadecene (ODE) as a solvent (dispersion medium) was added to the recovered precipitate to thereby disperse the precipitate, and a ZnSe-ODE dispersion was obtained.

Subsequently, 35 mL of the ZnSe-ODE dispersion was heated at 310° C. for 20 minutes in an inert gas (N₂) atmosphere while being stirred.

Next, a mixed solution of 2.2 mL of an S-TOP solution (2.2 M) as an S raw material and 11 mL of a zinc oleate (Zn(OLAc)₂) solution (0.8 M) as an organic zinc compound was prepared, 1.1 mL of the mixed solution was added to the ZnSe-ODE dispersion, and the mixture was heated at 310° C. for 20 minutes while being stirred, and thereby, as a core, ZnSe (core size of 5.3 nm) was covered with ZnS as a shell. In the present synthesis example, this operation (covering with a shell) was repeated twelve times.

Subsequently, ethanol was added to the reaction solution (ZnSe/ZnS dispersion) to generate a precipitate, and the solution was centrifuged to recover the precipitate. Next, hexane was added as a solvent (dispersion medium) to the precipitate, and the precipitate was dispersed.

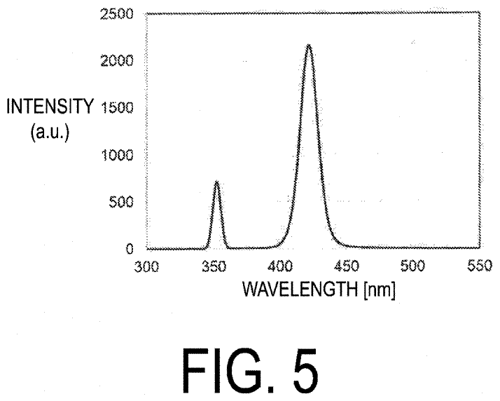

The fluorescence wavelength and the fluorescence full-width at half-maximum of the ZnSe/ZnS dispersed in the hexane were measured using the fluorescence spectrometer described above. As shown in FIG. 5, the measurement results indicated optical characteristics including a fluorescence wavelength of approximately 423 nm and a fluorescence full-width at half-maximum of approximately 15 nm.

Furthermore, the fluorescence quantum yield of the ZnSe/ZnS dispersed in the hexane was measured using the quantum efficiency measurement system described above. The measurement results showed that the fluorescence quantum yield was approximately 60%. Furthermore, the fluorescence lifetime of the ZnSe/ZnS dispersed in the hexane was measured using the fluorescence lifetime measurement device described above, and was found to be 44 ns.

Additionally, the particle size (outermost particle size) of the ZnSe/ZnS dispersed in the hexane was measured using the scanning electron microscope described above. Furthermore, the X-ray diffraction spectrum of the ZnSe/ZnS dispersed in the hexane was measured using the X-ray diffraction (XRD) device described above.

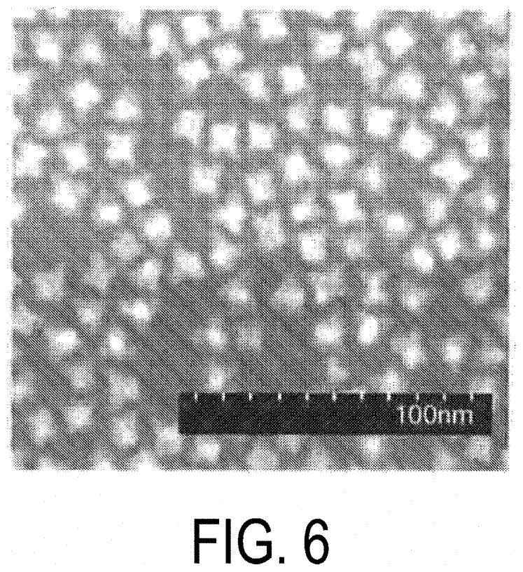

FIG. 6 is an image of a scanning electron micrograph of the ZnSe/ZnS obtained in the present embodiment. In addition, the spectrum indicated by the solid line in FIG. 4 is the X-ray diffraction spectrum of the ZnSe described above.

From the results illustrated in FIG. 6, the particle size (outermost particle size) of the ZnSe/ZnS was approximately 12 nm. Additionally, from the results indicated by the solid line in FIG. 4, it was found that the ZnSe/ZnS crystal was a cubic crystal, and the maximum peak intensity thereof was shifted 1.1° further to the higher angle side than the crystal peak position of ZnSe.

### Synthesis Example 2 of QD Phosphor Particles 25

A 100 mL reaction vessel was charged with 91 mg of anhydrous copper acetate (Cu(OAc)₂) as a Cu raw material (organic copper compound), 4.8 mL of oleylamine (OLAm) as a ligand, and 7.75 mL of octadecene (ODE) as a solvent. The raw materials in the reaction vessel were then heated and dissolved at 150° C. for 5 minutes in an inert gas (N₂) atmosphere while being stirred, and a solution was thereby obtained.

Next, 1.4 mL of an Se-DDT/OLAm solution (0.285 M) was added as an organic chalcogen compound to the solution, and the resulting mixture was heated at 150° C. for 30 minutes while being stirred. The reaction solution (Cu₂Se reaction liquid, copper chalcogenide) thereby obtained was cooled to room temperature.

Subsequently, 682 mg of anhydrous zinc acetate (Zn(OAc)₂) as an organic zinc compound, 10 mL of trioctylphosphine (TOP) as a solvent, and 0.4 mL of oleylamine (OLAm) as a ligand were added to the Cu₂Se reaction liquid, and the resulting mixture was heated at 180° C. for 10 minutes in an inert gas (N₂) atmosphere while being stirred. As a result, a metal exchange reaction occurred between Cu of the copper chalcogenide and Zn. The resulting reaction solution (ZnSe solution) was cooled to room temperature.

Next, ethanol was added to the reaction solution cooled to room temperature to generate a precipitate, and the reaction solution was centrifuged to recover the precipitate. Subsequently, 12 mL of octadecene (ODE) as a solvent (dispersion medium) was added to the recovered precipitate to thereby disperse the precipitate, and a ZnSe-ODE dispersion was obtained.

Subsequently, 682 mg of anhydrous zinc acetate (Zn(OAc)₂) as an organic zinc compound, 5 mL of trioctylphosphine (TOP) as a solvent (dispersion medium), and 0.5 mL of oleylamine (OLAm) and 6 mL of oleic acid (OLAc) as ligands were added to 12 mL of this ZnSe-ODE dispersion, and the mixture was heated at 280° C. for 30 minutes in an inert gas (N₂) atmosphere while being stirred. The resulting reaction solution (ZnSe dispersion) was cooled to room temperature.

The fluorescence wavelength and the fluorescence full-width at half-maximum of the ZnSe in this reaction solution (ZnSe dispersion) were measured using the fluorescence spectrometer described above. The measurement results indicated optical characteristics including a fluorescence wavelength of approximately 437 nm and a fluorescence full-width at half-maximum of approximately 15 nm.

In addition, ethanol was added to several mL of the reaction solution (ZnSe dispersion) to generate a precipitate, and the solution was centrifuged to recover the precipitate. Hexane was added as a solvent (dispersion medium) to the recovered precipitate, and the precipitate was dispersed.

The fluorescence quantum yield of the ZnSe dispersed in the hexane was measured using the quantum efficiency measurement system described above. The measurement results showed that the fluorescence quantum yield was approximately 37%. Furthermore, the fluorescence lifetime of the ZnSe dispersed in the hexane was measured using the fluorescence lifetime measurement device described above, and was found to be 13 ns.

Additionally, the particle size of the ZnSe dispersed in the hexane was measured using the scanning electron microscope described above. Furthermore, the X-ray diffraction spectrum of the ZnSe dispersed in the hexane was measured using the X-ray diffraction (XRD) device described above.

As a result, the particle size of the ZnSe was found to be approximately 6.0 nm. Additionally, it was found that the ZnSe crystal was a cubic crystal, and the peak position thereof was consistent with the crystal peak position of ZnSe.

Next, 23 mL of the reaction solution (ZnSe dispersion) was collected, ethanol was added thereto to generate a precipitate, and the mixture was centrifuged to recover the precipitate. 17.5 mL of octadecene (ODE) was added as a solvent (dispersion medium) to the recovered precipitate to thereby disperse the precipitate, and a ZnSe-ODE dispersion was obtained.

Subsequently, 1 mL of oleic acid (OLAc) as a ligand and 2 mL of trioctylphosphine (TOP) as a solvent (dispersion medium) were added into 17.5 mL of the ZnSe-ODE dispersion, and the mixture was heated at 320° C. for 10 minutes in an inert gas (N₂) atmosphere while being stirred.

Next, 0.5 mL of a mixed solution was added to the solution thereby obtained, the mixed solution containing 1 mL of an S-TOP solution (1 M) as an S raw material and 5 mL of a zinc oleate (Zn(OLAc)₂) solution (0.4 M) as an organic zinc compound was added, and the resulting mixture was heated at 320° C. for 10 minutes while being stirred, and thereby, ZnSe as a core was covered with ZnS as a shell. In the present synthesis example, this operation (covering with a shell) was repeated eight times.

2 mL of oleic acid (OLAc) was added as a ligand to the reaction solution (ZnSe/ZnS dispersion) thereby obtained, and the mixture was reacted at 320° C. for 10 minutes. Next, 2 mL of trioctylphosphine (TOP) was added as a solvent (dispersion medium) to this reaction solution (ZnSe/ZnS dispersion), and the mixture was heated at 320° C. for 10 minutes while being stirred. The resulting reaction solution (ZnSe/ZnS dispersion) was cooled to room temperature.

The fluorescence wavelength and the fluorescence full-width at half-maximum of the ZnSe/ZnS in the obtained reaction solution (ZnSe/ZnS dispersion) were measured using the fluorescence spectrometer described above. The measurement results indicated optical characteristics including a fluorescence wavelength of approximately 435 nm and a fluorescence full-width at half-maximum of approximately 16 nm.

Subsequently, ethanol was added to the reaction solution (ZnSe/ZnS dispersion) to generate a precipitate, and the solution was centrifuged to recover the precipitate. Next, hexane was added as a solvent (dispersion medium) to the precipitate, and the precipitate was dispersed.

The fluorescence quantum yield of the ZnSe/ZnS dispersed in the hexane was measured using the quantum efficiency measurement system described above. The measurement results showed that the fluorescence quantum yield was approximately 81%. Furthermore, the fluorescence lifetime of the ZnSe/ZnS dispersed in the hexane was measured using the fluorescence lifetime measurement device described above, and was found to be 12 ns.

Additionally, the particle size (outermost particle size) of the ZnSe/ZnS dispersed in the hexane was measured using the scanning electron microscope described above. Furthermore, the X-ray diffraction spectrum of the ZnSe/ZnS dispersed in the hexane was measured using the X-ray diffraction (XRD) device described above.

As a result, the particle size (outermost particle size) of the ZnSe/ZnS was found to be approximately 8.5 nm. Additionally, it was found that the ZnSe/ZnS crystal was a cubic crystal, and the maximum peak intensity thereof was shifted 0.4° further to a higher angle side than the crystal peak position of ZnSe.

### Synthesis Example 3 of QD Phosphor Particles 25

A 100 mL reaction vessel was charged with 91 mg of anhydrous copper acetate (Cu(OAc)₂) as a Cu raw material (organic copper compound), 4.8 mL of oleylamine (OLAm), and 7.75 mL of octadecene (ODE). In addition, the raw materials in the reaction vessel were then heated and dissolved at 170° C. for 5 minutes in an inert gas (N₂) atmosphere while being stirred, and a solution was thereby obtained.

Next, 1.4 mL of an Se-DDT/OLAm solution (0.285 M) was added as an organic chalcogen compound to the solution, and the resulting mixture was heated at 170° C. for 30 minutes while being stirred. The reaction solution (Cu₂Se reaction liquid, copper chalcogenide) thereby obtained was cooled to room temperature.

Subsequently, 922 mg of anhydrous zinc acetate (Zn(OAc)₂) as an organic zinc compound, 10 mL of trioctylphosphine (TOP) as a solvent, and 0.4 mL of oleylamine (OLAm) as a ligand were added to the Cu₂Se reaction liquid, and the resulting mixture was heated at 180° C. for 30 minutes in an inert gas (N₂) atmosphere while being stirred. As a result, a metal exchange reaction occurred between Cu of the copper chalcogenide and Zn. The resulting reaction solution (ZnSe solution) was cooled to room temperature.

Next, ethanol was added to the reaction solution cooled to room temperature to generate a precipitate, and the reaction solution was centrifuged to recover the precipitate. 12 mL of octadecene (ODE) was added as a solvent (dispersion medium) to the recovered precipitate to thereby disperse the precipitate, and a ZnSe-ODE dispersion was obtained.

Subsequently, 922 mg of anhydrous zinc acetate (Zn(OAc)₂) as an organic zinc compound, 5 mL of trioctylphosphine (TOP) as a solvent (dispersion medium), and 0.5 mL of oleylamine (OLAm) and 3 mL of oleic acid (OLAc) as ligands were added to 12 mL of this ZnSe-ODE dispersion, and the mixture was heated at 280° C. for 20 minutes in an inert gas (N₂) atmosphere while being stirred. The resulting reaction solution (ZnSe dispersion) was cooled to room temperature.

The fluorescence wavelength and the fluorescence full-width at half-maximum of the ZnSe in this reaction solution (ZnSe dispersion) were measured using the fluorescence spectrometer described above. The measurement results indicated optical characteristics including a fluorescence wavelength of approximately 448 nm and a fluorescence full-width at half-maximum of approximately 15 nm.

In addition, ethanol was added to several mL of the reaction solution (ZnSe dispersion) to generate a precipitate, and the solution was centrifuged to recover the precipitate. Hexane was added as a solvent (dispersion medium) to the recovered precipitate, and the precipitate was dispersed.

The fluorescence quantum yield of the ZnSe dispersed in the hexane was measured using the quantum efficiency measurement system described above. The measurement results showed that the fluorescence quantum yield was approximately 6%. Furthermore, the fluorescence lifetime of the ZnSe dispersed in the hexane was measured using the fluorescence lifetime measurement device described above, and was found to be 25 ns.

Additionally, the particle size of the ZnSe dispersed in the hexane was measured using the scanning electron microscope described above. Furthermore, the X-ray diffraction spectrum of the ZnSe dispersed in the hexane was measured using the X-ray diffraction (XRD) device described above.

As a result, the particle size of the ZnSe was found to be approximately 8.2 nm. Additionally, it was found that the ZnSe crystal was a cubic crystal, and the peak position thereof was consistent with the crystal peak position of ZnSe.

Next, 20 mL of the reaction solution (ZnSe dispersion) was collected, ethanol was added thereto to generate a precipitate, and the mixture was centrifuged to recover the precipitate. 17.5 mL of octadecene (ODE) was added as a solvent (dispersion medium) to the recovered precipitate to thereby disperse the precipitate, and a ZnSe-ODE dispersion was obtained.

Subsequently, 1 mL of oleic acid (OLAc) as a ligand and 2 mL of trioctylphosphine (TOP) as a solvent (dispersion medium) were added into 17.5 mL of the ZnSe-ODE dispersion, and the mixture was heated at 320° C. for 10 minutes in an inert gas (N₂) atmosphere while being stirred.

Next, 0.5 mL of a mixed solution was added to the solution thereby obtained, the mixed solution containing 0.2 mL of dodecanethiol (DDT) as an S raw material, 0.8 mL of trioctylphosphine (TOP) as a solvent (dispersion medium), and 5 mL of a zinc oleate (Zn(OLAc)₂) solution (0.4 M) as an organic zinc compound, and the resulting mixture was heated at 320° C. for 10 minutes while being stirred, and thereby, ZnSe as a core was covered with ZnS as a shell. In the present synthesis example, this operation (covering with a shell) was repeated eight times.

2 mL of oleic acid (OLAc) was added as a ligand to the reaction solution (ZnSe/ZnS dispersion) thereby obtained, and the mixture was reacted at 320° C. for 10 minutes. Next, 2 mL of trioctylphosphine (TOP) was added as a solvent (dispersion medium) to this reaction solution (ZnSe/ZnS dispersion), and the mixture was heated at 320° C. for 10 minutes while being stirred. The resulting reaction solution (ZnSe/ZnS dispersion) was cooled to room temperature.

The fluorescence wavelength and the fluorescence full-width at half-maximum of the ZnSe/ZnS in the obtained reaction solution (ZnSe/ZnS dispersion) were measured using the fluorescence spectrometer described above. The measurement results indicated optical characteristics including a fluorescence wavelength of approximately 447 nm and a fluorescence full-width at half-maximum of approximately 14 nm.

Subsequently, ethanol was added to the reaction solution (ZnSe/ZnS dispersion) to generate a precipitate, and the solution was centrifuged to recover the precipitate. Next, hexane was added as a solvent (dispersion medium) to the precipitate, and the precipitate was dispersed.

The fluorescence quantum yield of the ZnSe/ZnS dispersed in the hexane was measured using the quantum efficiency measurement system described above. The measurement results showed that the fluorescence quantum yield was approximately 62%. Furthermore, the fluorescence lifetime of the ZnSe/ZnS dispersed in the hexane was measured using the fluorescence lifetime measurement device described above, and was found to be 16 ns.

Additionally, the particle size (outermost particle size) of the ZnSe/ZnS dispersed in the hexane was measured using the scanning electron microscope described above. Furthermore, the X-ray diffraction spectrum of the ZnSe/ZnS dispersed in the hexane was measured using the X-ray diffraction (XRD) device described above.

As a result, the particle size (outermost particle size) of the ZnSe/ZnS was found to be approximately 9.8 nm. Additionally, it was found that the ZnSe/ZnS crystal was a cubic crystal, and the maximum peak intensity thereof was shifted 0.1° further to a higher angle side than the crystal peak position of ZnSe.

### Comparative Example

A 100 mL reaction vessel was charged with 0.833 mL of a zinc oleate (Zn(OLAc)₂-ODE dispersion (0.4 M) as an organic zinc compound and 10 mL of an Se-ODE dispersion (0.1 M) as an organic chalcogen compound, and the mixture was heated at 280° C. for 35 minutes in an inert gas (N₂) atmosphere while being stirred.

The fluorescence wavelength and the fluorescence full-width at half-maximum of the ZnSe in the reaction solution (ZnSe dispersion) thereby obtained were measured using a fluorescence spectrometer. The measurement results indicated optical characteristics including a fluorescence wavelength of approximately 455.0 nm and a fluorescence full-width at half-maximum of approximately 45.2 nm.

As described above, according to the above-described Synthesis Examples 1 to 3 of the QD phosphor particles 25, QD phosphor particles 25 having a particle size of within a range from 3 nm to 20 nm, and more preferably within a range from 5 nm to 20 nm can be obtained. Furthermore, it was found that in each case of the above-described Synthesis Examples 1 to 3 of the QD phosphor particles 25, the fluorescence quantum yield of the QD phosphor particles 25 thereby obtained was 5% or greater, and the fluorescence full-width at half-maximum was 25 nm or less. It was also possible to achieve a fluorescence lifetime of 50 ns or less. Furthermore, it was found that the fluorescence wavelength could be adjusted in a range from 410 nm to 470 nm. Additionally, it was found that in the core-shell structure (ZnSe/ZnS) formed of Zn, Se and S, the maximum intensity peak position in the X-ray diffraction spectrum was shifted from 0.05° to 1.2° to the higher angle side than the crystal peak with the ZnSe core alone.

From this peak shift to the higher angle side, it was determined that the lattice constant was changed by covering the ZnSe core with ZnS. From these results, it was also discovered that this peak shift amount and the coverage amount of ZnS are proportional. In addition, in the present results, the maximum intensity peak position in the X-ray diffraction spectrum of the QD phosphor particles 25 having the core-shell structure is almost close to the peak position of ZnS, but because blue (from 430 nm to 455 nm) light is emitted, it is thought that the core is ZnSe, and the core is covered with ZnS.

That is, from the blue light emission and the peak shift from the ZnSe core, it can be inferred that the QD phosphor particles 25 have a core-shell structure made of Zn, Se, and S.

Also, when the core is covered with a shell, the maximum intensity peak in the X-ray diffraction spectrum of the QD phosphor particles 25 moves to a higher angle side than the crystal peak in the X-ray diffraction spectrum of the core alone. Note that in the disclosure, the matter of “the maximum intensity peak in the X-ray diffraction spectrum of the QD phosphor particles 25 moves to a higher angle side than the crystal peak in the X-ray diffraction spectrum of the core alone” indicates that the QD phosphor particles 25 have a core-shell structure, and thereby the lattice constant of the QD phosphor particles 25 is smaller than that of the core alone.

As described above, when the core is ZnSe, and the maximum intensity peak in the X-ray diffraction spectrum of the QD phosphor particles 25 is shifted from 0.05° to 1.2° to the higher angle side than the crystal peak in the X-ray diffraction spectrum of the core alone, an even higher external quantum efficiency (EQE) can be achieved.

Also note that even when the core is ZnSeS, and the maximum intensity peak in the X-ray diffraction spectrum of the QD phosphor particles 25 is shifted from 0.05° to 1.2° to the higher angle side than the crystal peak in the X-ray diffraction spectrum of the core alone, as in the case in which the core is ZnSe, an even higher external quantum efficiency (EQE) can be realized.

Also, according to the present embodiment, as described above, environmentally-friendly QD phosphor particles can be provided by using QD phosphor particles that do not contain Cd, or in other words, QD phosphor particles that are composed of a non-Cd-based material.

### Manufacturing Example of Electroluminescent Element 1

Next, a manufacturing example of an electroluminescent element 1 in which the QD phosphor particles 25 are used will be described.

First, an anode electrode 12 having a thickness of 30 nm was formed by sputtering ITO on a substrate 11, which was a glass substrate. Next, a solution containing PEDOT:PSS or PEDOT was applied by spin coating onto the anode electrode 12. Subsequently, the solvent in the abovementioned solution applied onto the anode electrode 12 was volatilized by baking, and a hole injection layer 13 (PEDOT:PSS layer or a PEDOT layer) having a predetermined layer thickness was formed. Next, a solution containing TFB or PVK was applied on the hole injection layer 13 by spin coating. Subsequently, the solvent in the abovementioned solution applied onto the hole injection layer 13 was volatilized by baking, and thereby a hole transport layer 14 (TFB layer or PVK layer) having a layer thickness of 40 nm was formed. Next, a dispersion (liquid composition, QD solution) having dispersed therein ZnSeS-based QD phosphor particles 25 synthesized by the method disclosed in the above-described synthesis examples was applied by spin coating onto the hole transport layer 14. Subsequently, the solvent in the abovementioned dispersion applied onto the hole transport layer 14 was volatilized by baking, and thereby a QD layer 15 (ZnSeS-based QD phosphor particle layer) of a predetermined thickness was formed. Next, a solution containing ZnO nanoparticles or ZnMgO nanoparticles was applied onto the QD layer 15 by spin coating. The solvent in the abovementioned solution applied onto the QD layer 15 was then volatilized by baking, and thereby an electron transport layer 16 (ZnO nanoparticle layer or ZnMgO nanoparticle layer) having a predetermined layer thickness was formed. Next, a cathode electrode 17 having a thickness of 100 nm was formed by vacuum vapor depositing Al onto the electron transport layer 16. Next, the substrate 11 and the layered body formed on the substrate 11 were sealed with a sealing member in an N₂ atmosphere.

### Example 1

Using the method presented in the “Manufacturing Example of Electroluminescent Element 1” section described above, three types of electroluminescent elements 1 having the following layered structures were manufactured as Samples 1 to 3. Note that QD phosphor particles 25 synthesized by the method presented in the “Synthesis Example 1 of QD Phosphor Particles 25” section were used as the QD phosphor particles 25.

Sample 1: ITO (30 nm)/PEDOT:PSS (40 nm)/TFB (40 nm)/QD layer (15 nm)/ZnO (50 nm)/Al (100 nm)

Sample 2: ITO (30 nm)/PEDOT:PSS (40 nm)/TFB (40 nm)/QD layer (25 nm)/ZnO (50 nm)/Al (100 nm)

Sample 3: ITO (30 nm)/PEDOTT:PSS (40 nm)/TFB (40 nm)/QD layer (35 nm)/ZnO (50 nm)/Al (100 nm)

Next, a current (more precisely, a current density) from 0.03 mA/cm² to 75 mA/cm² was applied to each of the abovementioned samples. Then, by applying the current, the luminance value of the LB emitted from each sample was measured using an LED measurement apparatus (spectrometer). Note that as the LED measurement apparatus, an LED measurement apparatus available from Spectra Co-op (two-dimensional CCD small high sensitivity spectrometer: Solid Lambda CCD available from Carl Zeiss AG) was used.

Subsequently, the external quantum efficiency (EQE) of each sample was calculated on the basis of the measured luminance value. Note that currents of a plurality of current values selected from the above-described range were applied to each sample. As a result, a plurality of luminance values were measured for each sample. Of the plurality of EQE calculated on the basis of the plurality of luminance values measured for each sample, the EQE indicating the highest numerical value for a given sample was employed as the EQE of the given sample.

As a result, it was found that the EQE of Sample 1 (QD layer 15 nm) was 2.6%, the EQE of Sample 2 (QD layer 25 nm) was 2.2%, and the EQE of Sample 3 (QD layer 35 nm) was 2.3%.

### Example 2

Using the method presented in the “Manufacturing Example of Electroluminescent Element 1” section described above, four types of electroluminescent elements 1 having the following layered structures were manufactured as Samples 4 to 7. Note that in the present example as well, QD phosphor particles 25 synthesized by the method presented in the “Synthesis Example 1 of QD Phosphor Particles 25” section were used as the QD phosphor particles 25.

Sample 4: ITO (30 nm)/PEDOT (40 nm)/TFB (40 nm)/QD layer (15 nm)/ZnO (50 nm)/Al (100 nm)

Sample 5: ITO (30 nm)/PEDT (40 nm)/TFB (40 nm)/QD layer (15 nm)/ZnMgO (30 nm)/Al (100 nm)

Sample 6: ITO (30 nm)/PEDT (40 nm)/PVK (37 nm)/QD layer (15 nm)/ZnO (50 nm)/Al (100 nm)

Sample 7: ITO (30 nm)/PEDT:PSS (40 nm)/PVK (37 nm)/QD layer (15 nm)/ZnMgO (30 nm)/Al (100 nm)

The external quantum efficiency (EQE) of each sample was then calculated by the same method as in Example 1 for each of the above samples.

As a result, it was found that the EQE of Sample 4 (combination of TFB and ZnO) was 1.4%, the EQE of Sample 5 (combination of TFB and ZnMgO) was 2.6%, and the EQE of Sample 6 (combination of PVK and ZnO) was 2.7%, and the EQE of Sample 7 (combination of PVK and ZnMgO) was 8.0%.

### Example 3

Using the method presented in the “Manufacturing Example of Electroluminescent Element 1” section described above, three types of electroluminescent elements 1 having the following layered structures were manufactured as Samples 8 to 10. Note that in the present example as well, QD phosphor particles 25 synthesized by the method presented in the “Synthesis Example 1 of QD Phosphor Particles 25” section were used as the QD phosphor particles 25.

Sample 8: ITO (30 nm)/PEDOT:PSS (40 nm)/PVK (15 nm)/QD layer (15 nm)/ZnMgO (55 nm)/Al (100 nm)

Sample 9: ITO (30 nm)/PEDOT:PSS (40 nm)/PVK (25 nm)/QD layer (15 nm)/ZnMgO (55 nm)/Al (100 nm)

Sample 10: ITO (30 nm)/PEDOT:PSS (40 nm)/PVK (35 nm)/QD layer (15 nm)/ZnMgO (55 nm)/Al (100 nm)

The external quantum efficiency (EQE) of each sample was then calculated by the same method as in Example 1 for each of the above samples.

As a result, it was found that the EQE of Sample 8 (PVK layer 15 nm) was 14.7%, the EQE of Sample 9 (PVK layer 25 nm) was 14.4%, and the EQE of Sample 10 (PVK layer 35 nm) was 11.1%.

### Example 4

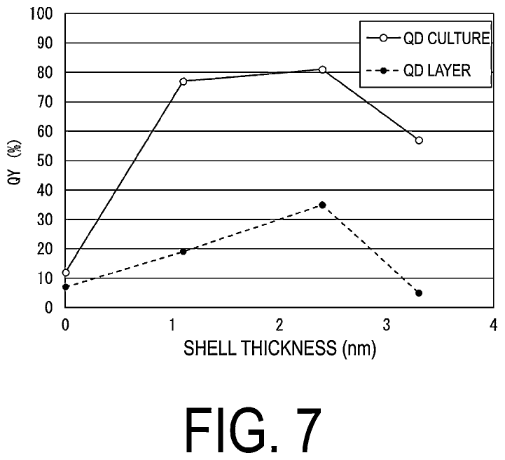

In the present example, a plurality of types of QD phosphor particles 25 having different shell thicknesses were synthesized by changing the number of times of coverage with a shell in the section of “Synthesis Example 1 of QD phosphor particles 25”. The relationship between the shell thickness and the fluorescence quantum yield (QY) of the QD phosphor particles 25 was then examined. FIG. 7 shows the examination results. Note that the quantum efficiency measurement system described above was used to measure the fluorescence quantum yield.

As shown in FIG. 7, it was possible to achieve a fluorescence quantum yield of 77% in the QD solution by setting the shell thickness to 1.1 nm. Furthermore, a fluorescence quantum yield (QY) of 81% in the QD solution was achieved by setting the shell thickness to 2.4 nm.

Also, the fluorescence full-width at half-maximum (FWHM) of the QD phosphor particles 25 thus obtained was 15 nm or less. Note that the fluorescence spectrometer described above was used to measure the fluorescence full-width at half-maximum (FWHM).

As shown in FIG. 7, to increase the fluorescence quantum yield, it is extremely important to increase the fluorescence quantum yield of the dispersion (QD solution) in which the QD phosphor particles 25 are dispersed, and it is important to form the QD layer 15 such that the fluorescence quantum yield does not decrease.

### Example 5

From the results shown in FIG. 7, it is clear that the fluorescence quantum yield tends to decrease when the shell thickness exceeds a certain value.

In the present example, the relationship between the number of times of coverage with a shell and the fluorescence quantum yield (QY) and fluorescence lifetime of the QD phosphor particles 25 was examined with regard to the QD phosphor particles 25 synthesized under conditions different from those of “Synthesis Example 1 of QD Phosphor Particles 25” to “Synthesis Example 3 of QD Phosphor Particles 25”. The results are shown in Table 1. Note that the quantum efficiency measurement system described above was used to measure the fluorescence quantum yield (QY). In addition, the fluorescence lifetime measurement device described above was used to measure the fluorescence lifetime.

TABLE 1

| | | | | Fluorescence | Fluorescence | |
|---|---|---|---|---|---|---|
| | | | | Lifetime | Lifetime | Shell |
| | Wavelength | FWHM | QY | (ns) | (ns) | Thickness |
| | (nm) | (nm) | (%) | 1/e | 1/10e | (nm) |
| Core | 428 | 14 | 28 | 13 | 56 | 0 |
| Coverage of 1 time | 429 | 13 | 22 | 11 | 46 | |
| Coverage of 2 times | 429 | 16 | 37 | 11 | 40 | |
| Coverage of 3 times | 429 | 13 | 46 | 10 | 36 | |
| Coverage of 4 times | 429 | 13 | 56 | 10 | 34 | 1.05 |
| Coverage of 6 times | 428 | 14 | 61 | 10 | 33 | |
| Coverage of 8 times | 425 | 14 | 61 | 11 | 37 | 2.4 |
| Coverage of 10 times | 423 | 14 | 55 | 12 | 47 | |
| Coverage of 12 times | 423 | 14 | 46 | 15 | 73 | 3.25 |

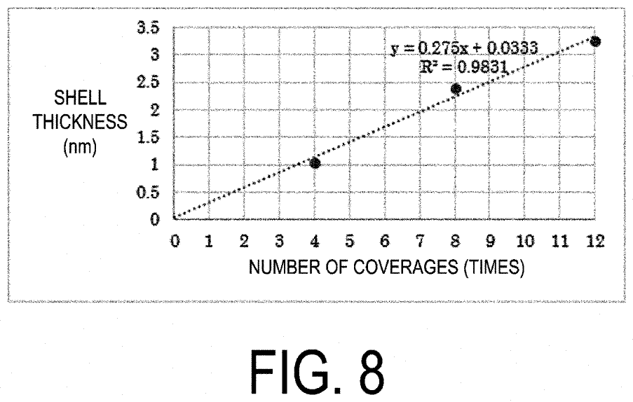

Also, the shell thickness is proportional to the number of coverages of the shell. When a linear approximation curve is drawn with the number of coverages of the shell denoted by x and the shell thickness denoted by y, the results shown in FIG. 8 are obtained.

From the results shown in FIG. 8, y=0.275x+0.0333, and it is clear that a shell thickness of approximately 0.28 nm is formed per coverage time.

From the results presented in FIG. 8 and Table 1, it is clear that when the number of coverage times is from 1 to 12, the thickness of the shell 25b can be set to a range from 0.3 nm to 3.3 nm. From the results shown in Table 1, it is also clear that when the number of coverage times is from 1 to 12, the fluorescence lifetime can be set to 15 ns or less, and a fluorescence quantum yield (QY) of 20% or greater can be obtained.

Also, from the results presented in FIG. 8 and Table 1, it is clear that when the number of coverage times is from 2 to 12, the thickness of the shell 25b can be set to a range from 0.5 nm to 3.3 nm. From the results shown in Table 1, it is also clear that when the number of coverage times is from 2 to 12, the fluorescence lifetime can be set to 15 ns or less, and a higher fluorescence quantum yield (QY) of 30% or greater can be obtained.

Furthermore, from the results presented in FIG. 8 and Table 1, it is clear that when the number of coverage times is from 3 to 12, the thickness of the shell 25b can be set to a range from 0.8 nm to 3.3 nm. From the results shown in Table 1, it is also clear that when the number of coverage times is from 3 to 12, the fluorescence lifetime can be set to 15 ns or less, and a higher fluorescence quantum yield (QY) of 40% or greater can be obtained.

Also, from the results presented in FIG. 8 and Table 1, it is clear that when the number of coverage times is from 4 to 10, the thickness of the shell 25b can be set to a range from 1.0 nm to 2.8 nm. From the results shown in Table 1, it is also clear that when the number of coverage times is from 4 to 12, the fluorescence lifetime can be set to 15 ns or less, and a higher fluorescence quantum yield (QY) of 50% or greater can be obtained.

Furthermore, from the results presented in FIG. 8 and Table 1, it is clear that when the number of coverage times is from 3 to 6, the thickness of the shell 25b can be set to a range from 0.8 nm to 1.7 nm. From the results shown in Table 1, it is also clear that when the number of coverage times is from 3 to 6, the fluorescence lifetime can be set to 10 ns or less, and a higher fluorescence quantum yield (QY) of 40% or greater can be obtained.

Also, from the results presented in FIG. 8 and Table 1, it is clear that when the number of coverage times is from 4 to 6, the thickness of the shell 25b can be set to a range from 1.0 nm to 1.7 nm. From the results shown in Table 1, it is also clear that when the number of coverage times is from 4 to 6, the fluorescence lifetime can be set to 10 ns or less, and a higher fluorescence quantum yield (QY) of 50% or greater can be obtained.

As mentioned above, the external quantum efficiency is proportional to the fluorescence quantum yield. Therefore, a high EQE can be realized by the configurations described above.

### Example 6

First, the QD phosphor particles 25 presented for Samples A to C were synthesized by the following method.

### Sample A

A reaction vessel was charged with anhydrous copper acetate (Cu(OAc)₂) as a Cu raw material (organic copper compound), oleylamine (OLAm) as a ligand, and octadecene (ODE) as a solvent. The raw materials in the reaction vessel were then heated and dissolved at 150° C. for 20 minutes in an inert gas (N₂) atmosphere while being stirred, and a solution was thereby obtained.

Next, an Se-DDT/OLAm solution (approximately 0.3 M) was added as an organic chalcogen compound to the solution, and the resulting mixture was heated at 150° C. for 10 minutes while being stirred. The reaction solution (Cu₂Se) thereby obtained was cooled to room temperature.

Subsequently, anhydrous zinc acetate (Zn(OAc)₂) as an organic zinc compound, trioctylphosphine (TOP) as a solvent, and oleylamine (OLAm) as a ligand were added to the Cu₂Se reaction liquid, and the resulting mixture was heated at 180° C. for 30 minutes in an inert gas (N₂) atmosphere while being stirred. As a result, a metal exchange reaction occurred between Cu of the copper chalcogenide and Zn. The resulting reaction solution (ZnSe solution) was cooled to room temperature.

Next, ethanol was added to the reaction solution cooled to room temperature to generate a precipitate, and the reaction solution was centrifuged to recover the precipitate. Octadecene (ODE) was added as a solvent (dispersion medium) to the recovered precipitate to thereby disperse the precipitate, and a ZnSe-ODE dispersion was obtained.

Subsequently, anhydrous zinc acetate (Zn(OAc)₂) as an organic zinc compound, trioctylphosphine (TOP) as a solvent (dispersion medium), and oleylamine (OLAm) and oleic acid as ligands were added to the ZnSe-ODE dispersion, and the mixture was heated at 280° C. for 30 minutes in an inert gas (N₂) atmosphere while being stirred. The resulting reaction solution (ZnSe dispersion) was cooled to room temperature.

Ethanol was then added to the reaction solution (ZnSe dispersion) to generate a precipitate, and the solution was centrifuged to recover the precipitate. Octadecene (ODE) was added as a solvent (dispersion medium) to the recovered precipitate to thereby disperse the precipitate, and a ZnSe-ODE dispersion was obtained.

The ZnSe-ODE dispersion was heated at 310° C. for 10 minutes in an inert gas (N₂) atmosphere while being stirred.

Next, a mixed solution of an S-TOP solution (2.2 M) as an S raw material and a zinc oleate (Zn(OLAc)₂) solution (0.8 M) as an organic zinc compound was prepared and added to the ZnSe-ODE dispersion, and the mixture was heated at 310° C. for 10 minutes while being stirred, and thereby, ZnSe (core size 5.3 nm) as a core was covered with ZnS as a shell. This operation was repeated eight times. The resulting reaction solution (ZnSe/ZnS) was cooled to room temperature.

The reaction solution was then measured with the above-mentioned fluorescence spectrometer, and the measurement results indicated optical characteristics including a fluorescence wavelength of approximately 423 nm and a fluorescence full-width at half-maximum of approximately 15 nm.

### Sample B

A reaction vessel was charged with anhydrous copper acetate (Cu(OAc)₂) as a Cu raw material (organic copper compound), oleylamine (OLAm) as a ligand, and octadecene (ODE) as a solvent. The raw materials in the reaction vessel were then heated and dissolved at 150° C. for 5 minutes in an inert gas (N₂) atmosphere while being stirred, and a solution was thereby obtained.

Next, an Se-DDT/OLAm solution (approximately 0.3 M) was added as an organic chalcogen compound to the solution, and the resulting mixture was heated at 150° C. for 30 minutes while being stirred. The reaction solution (Cu₂Se) thereby obtained was cooled to room temperature.

Subsequently, anhydrous zinc acetate (Zn(OAc)₂) as an organic zinc compound, trioctylphosphine (TOP) as a solvent, and oleylamine (OLAm) as a ligand were added to the Cu₂Se reaction liquid, and the resulting mixture was heated at 180° C. for 10 minutes in an inert gas (N₂) atmosphere while being stirred. As a result, a metal exchange reaction occurred between Cu of the copper chalcogenide and Zn. The resulting reaction solution (ZnSe) was cooled to room temperature.

Next, ethanol was added to the reaction solution cooled to room temperature to generate a precipitate, and the reaction solution was centrifuged to recover the precipitate. Octadecene (ODE) was added as a solvent (dispersion medium) to the recovered precipitate to thereby disperse the precipitate, and a ZnSe-ODE dispersion was obtained.

Subsequently, anhydrous zinc acetate (Zn(OAc)₂) as an organic zinc compound, trioctylphosphine (TOP) as a solvent (dispersion medium), and oleylamine (OLAm) and oleic acid (OLAc) as ligands were added to the ZnSe-ODE dispersion, and the mixture was heated at 280° C. for 30 minutes in an inert gas (N₂) atmosphere while being stirred. The resulting reaction solution (ZnSe dispersion) was cooled to room temperature.

Ethanol was then added to the reaction solution (ZnSe dispersion) to generate a precipitate, and the solution was centrifuged to recover the precipitate. Octadecene (ODE) was added as a solvent (dispersion medium) to the recovered precipitate to thereby disperse the precipitate, and a ZnSe-ODE dispersion was obtained.

Subsequently, oleic acid (OLAc) and trioctylphosphine (TOP) were added as ligands into the ZnSe-ODE dispersion, and the mixture was heated at 320° C. for 10 minutes in an inert gas (N₂) atmosphere while being stirred.

Next, a mixed solution was added to the solution thereby obtained, the mixed solution containing an S-TOP solution (1 M) as an S raw material and a zinc oleate (Zn(OLAc)₂) solution (0.4 M) as an organic zinc compound, and the resulting mixture was heated at 320° C. for 10 minutes while being stirred, and thereby, ZnSe (core size of approximately 6 nm) as a core was covered with ZnS as a shell. This operation was repeated eight times.

Oleic acid (OLAc) was then added as a ligand to the reaction solution (ZnSe/ZnS dispersion) thereby obtained, and the mixture was reacted at 320° C. for 10 minutes. Next, trioctylphosphine (TOP) was added as a solvent (dispersion medium) to this reaction solution (ZnSe/ZnS dispersion), and the mixture was heated at 320° C. for 10 minutes while being stirred. The resulting reaction solution (ZnSe/ZnS dispersion) was cooled to room temperature.

The fluorescence wavelength and the fluorescence full-width at half-maximum of the ZnSe/ZnS in the obtained reaction solution (ZnSe/ZnS dispersion) were measured using the fluorescence spectrometer described above. The measurement results indicated optical characteristics including a fluorescence wavelength of approximately 435 nm and a fluorescence full-width at half-maximum of approximately 16 nm.

### Sample C

A reaction vessel was charged with anhydrous copper acetate (Cu(OAc)₂) as a Cu raw material (organic copper compound), oleylamine (OLAm) as a ligand, and octadecene (ODE) as a solvent. The raw materials in the reaction vessel were then heated and dissolved at 165° C. for 10 minutes in an inert gas (N₂) atmosphere while being stirred, and a solution was thereby obtained.

Next, an Se-DDT/OLAm solution (approximately 0.7 M) was added as an organic chalcogen compound to the solution, and the resulting mixture was heated at 165° C. for 30 minutes while being stirred. The reaction solution (Cu₂Se) thereby obtained was cooled to room temperature.

Subsequently, anhydrous zinc acetate (Zn(OAc)₂) as an organic zinc compound, trioctylphosphine (TOP) as a solvent, and oleylamine (OLAm) as a ligand were added to the Cu₂Se reaction liquid, and the resulting mixture was heated at 180° C. for 45 minutes in an inert gas (N₂) atmosphere while being stirred. As a result, a metal exchange reaction occurred between Cu of the copper chalcogenide and Zn. The resulting reaction solution (ZnSe) was cooled to room temperature.

Ethanol was then added to the reaction solution cooled to room temperature to generate a precipitate, and the reaction solution was centrifuged to recover the precipitate, after which octadecene (ODE) was added to the precipitate to disperse the precipitate.

Subsequently, anhydrous zinc acetate (Zn(OAc)₂), trioctylphosphine (TOP), oleylamine (OLAm), and oleic acid (OLAc) were added to the ZnSe-ODE dispersion, and the mixture was heated at 280° C. for 20 minutes in an inert gas (N₂) atmosphere while being stirred. The obtained reaction solution (ZnSe) was cooled to room temperature.

Ethanol was then added to the ZnSe reaction liquid to generate a precipitate, and the solution was centrifuged to recover the precipitate. Octadecene (ODE) was added as a solvent (dispersion medium) to the recovered precipitate to thereby disperse the precipitate, and a ZnSe-ODE dispersion was obtained.

Subsequently, oleic acid (OLAc) as a ligand and trioctylphosphine (TOP) as a solvent (dispersion medium) were added into the ZnSe-ODE dispersion, and the mixture was heated at 320° C. for 10 minutes in an inert gas (N₂) atmosphere while being stirred.

A mixed solution was added to this solution, the mixed solution including an S-TOP solution (1M), a zinc oleate (Zn(OLAc)₂) solution (0.8 M), dodecanethiol (DDT), trioctylphosphine (TOP), and octadecene (ODE), and the resulting mixture was then heated at 320° C. for 10 minutes while being stirred. This operation was repeated four times.

Ethanol was then added to the thereby obtained reaction solution to generate a precipitate, and the solution was centrifuged to recover the precipitate. Octadecene (ODE) was added to the recovered precipitate to thereby disperse the precipitate, and a ZnSe-ODE dispersion was obtained.

Subsequently, oleic acid (OLAc) and trioctylphosphine (TOP) were added into the ZnSe-ODE dispersion, and the mixture was heated at 320° C. for 10 minutes in an inert gas (N₂) atmosphere while being stirred.

Next, a mixed solution was added to the solution thereby obtained, the mixed solution including a zinc oleate (Zn(OLAc)₂) solution (0.8 M), dodecanethiol (DDT), trioctylphosphine (TOP), and octadecene (ODE), and the resulting mixture was then heated at 320° C. for 10 minutes while being stirred. This operation was repeated ten times.

Next, the following operation of washing, re-dispersion, and covering was implemented three times. Specifically, ethanol was added to the obtained reaction solution to generate a precipitate, and the solution was centrifuged to recover the precipitate. Octadecene (ODE) was then added to the precipitate to thereby disperse the precipitate, and a ZnSe-ODE dispersion was obtained.

Subsequently, oleic acid (OLAc) and trioctylphosphine (TOP) were added into the ZnSe-ODE dispersion, and the mixture was heated at 320° C. for 10 minutes in an inert gas (N₂) atmosphere while being stirred.

Next, a mixed solution was added to the reaction solution thereby obtained, the mixed solution including a zinc oleate (Zn(OLAc)₂) solution (0.8 M), dodecanethiol (DDT), trioctylphosphine (TOP), and octadecene (ODE), and the resulting mixture was then heated at 320° C. for 10 minutes while being stirred. This operation was repeated six times.

Through the above operation, ZnSe (core size of approximately 8 nm) as a core was coated with ZnSeS and ZnS as a shell.

Subsequently, the fluorescence wavelength and the fluorescence full-width at half-maximum of the QD phosphor particles in the obtained reaction solution were measured using the fluorescence spectrometer described above. The measurement results indicated optical characteristics including a fluorescence wavelength of approximately 444 nm and a fluorescence full-width at half-maximum of approximately 15 nm.

The fluorescent peak intensity (λ), the fluorescence full-width at half-maximum (FWHM), the fluorescence quantum yield (QY) of the QD solution, and CIE chromaticity coordinates of the QD phosphor particles 25 were then measured. Note that the X-ray diffraction device described above was used to measure the fluorescence peak intensity. Furthermore, the fluorescence spectrometer described above was used to measure the fluorescence full-width at half-maximum. In addition, the quantum efficiency measurement system described above was used to measure the fluorescence quantum yield.

Subsequently, three types of electroluminescent elements 1 (QLED) having the following layered structures were manufactured using the method described in “Manufacturing Example of Electroluminescent Element 1” section described above.

### Sample A

ITO (30 nm)/PEDOT:PSS (40 nm)/PVK (30 nm)/QD (15 nm)/MgZnO (55 nm)/Al (100 nm) Sample B

ITO (100 nm)/PEDOT:PSS (40 nm)/PVK (40 nm)/QD (20 nm)/ZnO (50 nm)/Al (100 nm) Sample C

ITO (100 nm)/PEDOT:PSS (40 nm)/PVK (40 nm)/QD (20 nm)/ZnO (50 nm)/Al (100 nm)

The external quantum efficiency (EQE) of these electroluminescent elements 1 was then measured using the same method as in Example 1. The measurements results are listed in Table 2.

TABLE 2

| | | | QY | EQE | |
|---|---|---|---|---|---|
| | λ | FWHM | (QD Solution) | (QLED) | CIE |
| Sample | (nm) | (nm) | (%) | (%) | (x, y) |
| A | 428 | 14 | 85 | 14.7 | (0.1688, 0.0146) |
| B | 438 | 14 | 70 | 12.0 | (0.1664, 0.0135) |
| C | 445 | 15 | 64 | 10.7 | (0.1566, 0.0207) |

As described above, according to the present embodiment, an electroluminescent element 1 that emits blue light without using Cd and can realize a high EQE can be provided.

Note that as demonstrated in Example 3, for example, the electroluminescent element 1 is more preferably configured such that the hole injection layer 14 contains PEDOT:PSS, and the hole transport layer 14 contains PVK.

According to the known common knowledge of a person skilled in the art, from the perspective of the energy level, when PEDOT:PSS (having a valence bond maximum (VBM) of, for example, 5.4 eV) is used in the hole injection layer, the injection of positive holes into the QD layer containing the QD phosphor particles (with a VBM of, for example, 5.5 eV) having ZnSe as the core is considered to be advantageous in terms of the EQE because the injection barrier of TFB (with a VBM of, for example, 5.4 eV) is smaller than that of PVK (with a VBM of, for example, 5.8 eV).

However, the inventors of the present application newly discovered that the use of PVK in the hole transport layer 14 results in a better improvement of EQE than the use of TFB in the hole transport layer 14. In other words, an even higher EQE can be realized by configuring the electroluminescent element 1 such that the hole injection layer 13 and the hole transport layer 14 are provided, in this order from the anode electrode 12 side, between the anode electrode 12 and the QD layer 15, the hole injection layer 13 contains PEDOT:PSS, and the hole transport layer 14 contains PVK.

The reason for this is thought to be as follows. When the QD phosphor particles 25 have a ZnSe/ZnS core-shell structure and the allowable lattice mismatch of ZnSe/ZnS is calculated, the allowable lattice mismatch is approximately 4.3% when the thickness of the shell made of ZnS is 2 nm. Therefore, defects are relatively easily introduced into the shell in a system in which the core-shell structure of ZnSe/ZnS is used in the QD phosphor particles 25. Thus, it is thought that a hole injection path in which a defect level is used as the path can be formed through these defects, and thus unlike the common technical knowledge of a person skilled in the art, the EQE is improved by using PVK in the hole transport layer 14.

Also, as demonstrated in Example 2 for example, an even higher EQE can be realized by configuring the electroluminescent element 1 such that an electron transport layer 16 is provided between the cathode electrode 17 and the QD layer 15, and the electron transport layer 16 contains ZnMgO.

### Modified Example

In the description above, A BE-type electroluminescent element 1 was described. However, the electroluminescent element 1 according to the present embodiment is not limited thereto. As described above, the electroluminescent element 1 may be a top-emitting (TE) type electroluminescent element. Note that an example of a TE type electroluminescent element is presented in a third embodiment described below.

In a case where the electroluminescent element 1 is of the TE-type, the LB is emitted from the QD layer 15 in the upward direction of FIG. 1. Thus, a light-reflective electrode is used for the anode electrode 12, and a light-transmissive electrode is used for the cathode electrode 17. A substrate having low translucency (e.g., a plastic substrate) may be used as the substrate 11.

In the TE-type electroluminescent element 1, there are fewer members such as TFTs, for example, that obstruct the path of the LB on the LB light-emitting surface side (emission direction) than in the BE-type electroluminescent element 1. As a result, since the aperture ratio is large, the EQE can be further improved.

### Second Embodiment

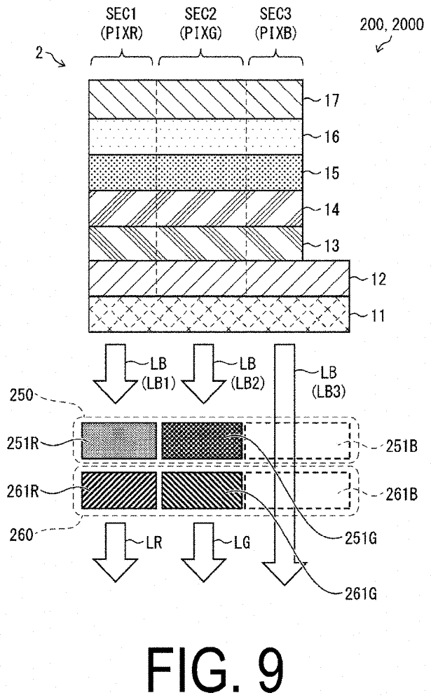

FIG. 9 is a cross-sectional view schematically illustrating an overall configuration of main portions of a display device 2000 according to the present embodiment. The display device 2000 includes a light-emitting device 200. The light-emitting device 200 includes an electroluminescent element 2, a wavelength conversion sheet 250 (wavelength conversion member), and a color filter (CF) sheet 260 (CF member). The light-emitting device 200 may be used as, for example, a backlight for the display device 2000. The light-emitting device 200 configures one picture element including an R pixel (PIXR), a G pixel (PIXG), and a B pixel (PIXB) in the display device 2000.

The display device 2000 includes an R pixel (PIXR), a G pixel (PIXG), and a B pixel (PIXB). Note that the R pixel may be referred to as an R subpixel. This similarly applies to the G pixel and the B pixel.

The electroluminescent element 2 is a BE-type electroluminescent element similar to the electroluminescent element 1. Thus, in the example illustrated in FIG. 9, it is assumed that a display portion (not illustrated) (e.g., a display panel) of the display device 2000 is provided below the electroluminescent element 2.

In the electroluminescent element 2, the QD layer 15 (and each corresponding layer) is partitioned into three subregions (SEC1 to SEC3) in the horizontal direction. More specifically, in the electroluminescent element 2, a plurality of TFTs (not illustrated) are provided in each of the SEC1 to SEC3 so that individual voltages can be applied to the QD layer 15. Accordingly, the light emission state of the QD layer 15 can be individually controlled in each of the SEC1 to SEC3.

The LBs that are emitted from the SEC1 to SEC3 are also referred to below as LB1 to LB3, respectively. In the example of FIG. 9, the SEC1 is set to the PIXR, the SEC2 is set to the PIXG, and the SEC3 is set to the PIXB as the respective corresponding subregions.

The wavelength conversion sheet 250 is provided below the electroluminescent element 2 at positions corresponding to the SEC1 to SEC3. The wavelength conversion sheet 250 converts a wavelength of a portion of the LB (LB1 and LB2) emitted from the QD layer 15. The wavelength conversion sheet 250 includes a red wavelength conversion layer 251R (red wavelength conversion member) and a green wavelength conversion layer 251G (green wavelength conversion member). The wavelength conversion sheet 250 further includes a blue light transmission layer 251B.

The red wavelength conversion layer 251R is provided at a position corresponding to the SEC1. In other words, the PIXR includes the red wavelength conversion layer 251R. The red wavelength conversion layer 251R includes red QD phosphor particles (not illustrated) that emit red light (LR) as fluorescence by receiving the LB1 as excitation light. In other words, the red wavelength conversion layer 251R converts the LB1 into the LR. The red wavelength conversion layer 251R may be referred to as a red quantum dot light-emitting layer.

As described above, unlike the QD layer 15, the red wavelength conversion layer 251R emits light by photoluminescence (PL). The amount of light of the LR can be changed by adjusting the amount of light of the LB1, which is the excitation light. This similarly applies to the green wavelength conversion layer 251G described below. In the SEC1, the LR passing through the red CF 261R is emitted toward the display portion.

The green wavelength conversion layer 251G is provided at a position corresponding to the SEC2. In other words, the PIXG includes the green wavelength conversion layer 251G. The green wavelength conversion layer 251G includes green QD phosphor particles (not illustrated) that emit green light (LG) as fluorescence by receiving the LB2 as excitation light. In other words, the green wavelength conversion layer 251G converts the LB2 into the LG. The green wavelength conversion layer 251G may be referred to as a green quantum dot light-emitting layer. In the SEC2, the LG passing through the green CF 261G is emitted toward the display portion.

The blue light transmission layer 251B is provided at a position corresponding to the SEC3. The blue light transmission layer 251B transmits the LB3. The material of the blue light transmission layer 251B is not particularly limited. The material is preferably a material having a particularly high light transmittance in at least the blue wavelength band (e.g., a glass or a resin having translucency). According to the above configuration, in the SEC3, the LB3 transmitted through the blue light transmission layer 251B is emitted toward the display portion.

In the present embodiment, a blue light transmission layer (hereinafter, a blue light transmission layer 261B) similar to that of the blue light transmission layer 251B is also provided in the CF sheet 260. The blue light transmission layer 261B is also provided at a position corresponding to the SEC3. The material of the blue light transmission layer 261B may be the same as or different from the material of the blue light transmission layer 251B. In the present embodiment, the LB3 transmitted through the blue light transmission layer 251B further passes through the blue light transmission layer 261B and is directed toward the display portion.

Note that the blue light transmission layer 261B of the CF sheet 260 may be provided with a blue CF. Alternatively, in a case where the CF sheet 260 is not provided, the blue CF may be provided in the blue light transmission layer 251B of the wavelength conversion sheet 250.

As described above, according to the light-emitting device 200, light in which the LR, the LG, and the LB3 are mixed (mixed light) can be supplied to the display portion. Accordingly, by appropriately adjusting each of the amounts of light of the LR, the LG, and the LB3, the desired tinge can be represented by the above-described mixed light.

The materials of the red QD phosphor particles and the green QD phosphor particles can be freely selected. As described above, as an example, InP is suitably used as the non-Cd-based material. When InP is used, the fluorescence full-width at half-maximum can be made relatively narrow, and high luminous efficiency can be obtained.

As described in the first embodiment, by using the QD layer 15 as the blue light source, the half width of the blue light and the fluorescent peak wavelength can be controlled precisely compared with before. In other words, the monochromaticity of the blue light (LB3) in the PIXB can be improved. In view of this, in the light-emitting device 200, the wavelength conversion sheet 250 (more specifically, the red wavelength conversion layer 251R and the green wavelength conversion layer 251G) is provided as a red light source and a green light source.

According to the red wavelength conversion layer 251R, the monochromaticity of the red light (LR) in the PIXR can be improved. Similarly, according to the green wavelength conversion layer 251G, the monochromaticity of the green light (LG) in the PIXG can be improved. Thus, according to the light-emitting device 200, the display device 2000 having excellent display quality (color reproducibility, in particular) can be realized.

However, the wavelength conversion sheet 250 cannot necessarily convert all of the LB (LB1 and LB2) received in the SEC1 and the SEC2 into light of a different wavelength. Specifically, the red wavelength conversion layer 251R cannot necessarily convert all of the LB1 into the LR. In other words, part of the LB1 is not absorbed in the red wavelength conversion layer 251R and passes through the red wavelength conversion layer 251R. Similarly, part of the LB2 is not absorbed in the green wavelength conversion layer 251G and passes through the green wavelength conversion layer 251G. Hereinafter, the LB1 passing through the red wavelength conversion layer 251R is referred to as a first residual blue light. The LB2 passing through the green wavelength conversion layer 251G is referred to as a second residual blue light.

Thus, in order to reduce the effect of the LB passing through the wavelength conversion sheet 250 in the SEC1 and SEC2 (the first residual blue light and the second residual blue light), the CF sheet 260 is provided at a position corresponding to the wavelength conversion sheet 250. The CF sheet 260 is provided below the wavelength conversion sheet 250. In other words, the CF sheet 260 is provided so as to cover the wavelength conversion sheet 250 when viewed from the display surface. The CF sheet 260 includes a red CF 261R and a green CF 261G. As described above, the CF sheet 260 further includes a blue light transmission layer 261B.

In order to reduce the effect of the first residual blue light in the PIXR, the red CF 261R is provided at a position corresponding to the SEC1 (a position corresponding to the red wavelength conversion layer 251R). Similarly, in order to reduce the effect of the second residual blue light in the PIXG, the green CF 261G is provided at a position corresponding to the SEC2 (a position corresponding to the green wavelength conversion layer 251G).

The red CF 261R and the green CF 261G selectively transmit red light and green light, respectively. Specifically, the red CF 261R has a high light transmittance in the red wavelength band and a relatively low light transmittance in other wavelength bands. The green CF 261G has a high light transmittance in the green wavelength band and a relatively low light transmittance in other wavelength bands. In the second embodiment, it is preferable that both of the red CF 261R and the green CF 261G have a particularly low light transmittance in the blue wavelength band.

By providing the CF sheet 260, the first residual blue light directed toward the display portion can be blocked by the red CF 261R. Similarly, the second residual blue light directed toward the display portion can be blocked by the green CF 261G. As a result, the monochromaticity of each of the LR and the LG in the display portion can be further improved. Thus, the display quality of the display device 2000 can be further enhanced. However, depending on the display quality required for the display device 2000, the CF sheet 260 can be omitted.

The wavelength conversion sheet 250 and the CF sheet 260 may be formed integrally. For example, by forming the CF sheet 260 on the upper face of the wavelength conversion sheet 250 at the positions corresponding to the SEC1 to SEC3, an integral sheet (hereinafter, referred to as a “wavelength conversion/CF sheet”) may be manufactured. The wavelength conversion/CF sheet may be disposed below the electroluminescent element 2 such that the CF sheet 260 side of the wavelength conversion/CF sheet faces the display surface.

As another example, by forming the wavelength conversion sheet 250 on the upper face of the CF sheet 260 at the positions corresponding to the SEC1 to SEC3, the wavelength conversion/CF sheet may be manufactured.

As yet another example, the wavelength conversion/CF sheet may be manufactured by forming the red wavelength conversion layer 251R and the green wavelength conversion layer 251G on the upper face of the CF sheet 260 at the respective positions corresponding to the SEC1 and SEC2. As described above, the wavelength conversion sheet may be provided only at positions corresponding to the SEC1 and the SEC2. In this case, the formation of the blue light transmission layer 251B can be omitted.

### Supplement

If the film thickness of the wavelength conversion sheet 250 (more specifically, the film thickness of each of the red wavelength conversion layer 251R and the green wavelength conversion layer 251G; hereinafter, “Dt”) is too small (e.g., less than 0.1 μm), the absorption of the LB in the wavelength conversion sheet 250 is insufficient. As a result, the wavelength conversion efficiency of the wavelength conversion sheet 250 decreases. On the other hand, when the Dt is too large (e.g., when the Dt exceeds 100 μm), the light extraction efficiency in the wavelength conversion sheet 250 decreases. The decrease in the light extraction efficiency is due to, for example, the fluorescence (LR and LG) generated in the wavelength conversion sheet 250 being scattered by the wavelength conversion sheet 250 itself.

As described above, from the perspective of improving the efficiency of the light-emitting device 200, the Dt is preferably 0.1 μm to 100 μm. In order to further improve the efficiency, the Dt is particularly preferably 5 μm to 50 μm. As an example, the Dt can be set to a desired value by forming the wavelength conversion sheet 250 by using a binder.

The material of the binder can be freely selected, but an acrylic resin is preferably used as the material. This is because the acrylic resin has high transparency and can effectively disperse the QDs.

### Modified Example

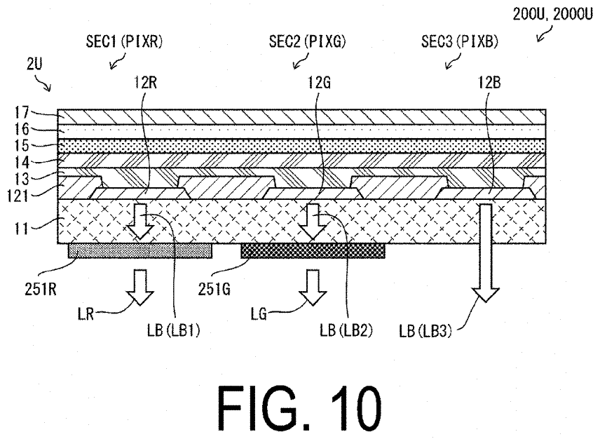

FIG. 10 is a diagram for describing one modified example of the display device 2000 (hereinafter, a display device 2000U). The light-emitting device and the electroluminescent element of the display device 2000U are referred to as a light-emitting device 200U and an electroluminescent element 2U, respectively. In FIG. 10, for simplicity of illustration, some of the members illustrated in FIG. 9 are omitted.

In the display device 2000U, a first electrode (e.g., an anode electrode) is provided individually for the PIXR, the PIXG, and the PIXB. Hereinafter, (i) a first electrode provided on the PIXR is referred to as a red first electrode 12R, (ii) a first electrode provided on the PIXG is referred to as a green first electrode 12G, and (iii) a first electrode provided on the PIXB is referred to as a blue first electrode 12B. In the example of FIG. 10, an edge cover 121 is provided at each end portion of the red first electrode 12R, the green first electrode 12G, and the blue first electrode 12B.

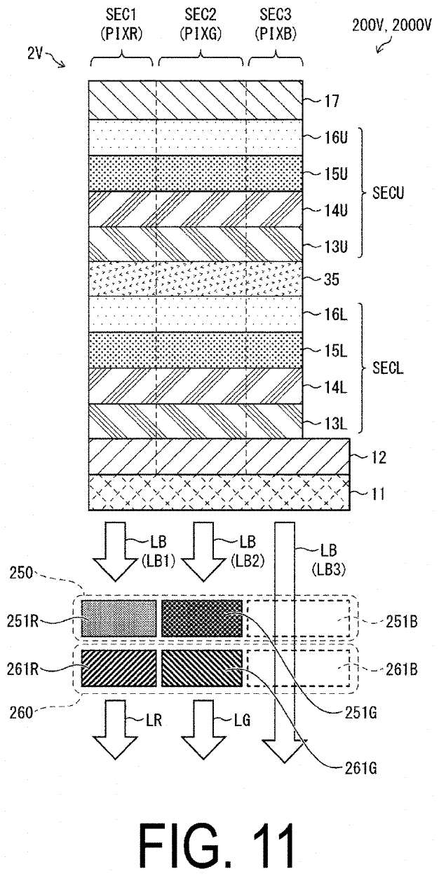

In the display device 2000U, the QD layer 15 is interposed between (i) the red first electrode 12R, the green first electrode 12G, and the blue first electrode 12B and (ii) the cathode electrode 17 (a second electrode). Additionally, the QD layer 15 is shared by the PIXR, the PIXG, and the PIXB. The cathode electrode 17 (the second electrode) is also shared by the PIXR, the PIXG, and the PIXB. This similarly applies to other layers. The display device 2000U can be said to be one specific example of the configuration of the display device 2000. The configuration illustrated in FIG. 10 is also applicable to the configurations of FIG. 11 to FIG. 13 described below.

### Modified Example

FIG. 11 is a diagram for describing another modified example of the display device 2000 (hereinafter, a display device 2000V). The light-emitting device and the electroluminescent element of the display device 2000V are referred to as a light-emitting device 200V and an electroluminescent element 2V, respectively. The electroluminescent element 2V is a tandem-type electroluminescent element configured based on the electroluminescent element 2.

Specifically, unlike the electroluminescent element 2, the electroluminescent element 2V includes a lower light-emitting unit (SECL) and an upper light-emitting unit (SECU) as a pair of light-emitting units. The SECL is formed on an upper face of the anode electrode 12. On the other hand, the SECU is formed on a lower face of the cathode electrode 17. Each of the SECL and the SECU includes layers similar to the hole injection layer 13 to the electron transport layer 16 of the electroluminescent element 2. In the example of FIG. 11, the layers of the SECL are referred to as a hole injection layer 13L to an electron transport layer 16L, and the layers of the SECU are referred to as a hole injection layer 13U to an electron transport layer 16U. Also, in the electroluminescent element 2V, a charge generating layer 35 is further provided between the SECL and the SECU.

An example of a method for manufacturing the electroluminescent element 2V is as follows. First, after film formation of the anode electrode 12, the SECL (the hole injection layer 13L to the electron transport layer 16L) is formed on the upper face of the anode electrode 12 by similar techniques as those in the first embodiment. Then, the charge generating layer 35 is formed on the upper face of the electron transport layer 16L. Subsequently, the SECU (the hole injection layer 13U to the electron transport layer 16U) is formed on the upper face of the charge generating layer 35. Finally, the cathode electrode 17 is formed on the upper face of the electron transport layer 16U.

In the electroluminescent element 2V, two QD layers (QD layers 15L and 15U) are provided as blue light sources. Thus, according to the electroluminescent element 2V, the amount of light of the LB can be increased as compared with the electroluminescent element 2. Thus, the amounts of light of the LR and the LG can also be increased as compared with those of the electroluminescent element 2.

As described above, according to the electroluminescent element 2V, the light emission intensity of the light-emitting device 200V can be increased as compared with the light-emitting device 200. Thus, the viewability of the image displayed on the display device 2000V can be increased as compared with the display device 2000. In other words, the display device 2000V having more excellent display quality can be realized.

The charge generating layer 35 of the electroluminescent element 2V is provided as a buffer layer between the electron transport layer 16L and the hole injection layer 13U. By providing the charge generating layer 35, the efficiency of recombination of the positive holes and the electrons in the QD layers 15L and 15U can be improved. In other words, the amount of light of the LB can be increased more effectively. However, depending on the display quality required for the display device 2000V, the charge generating layer 35 can be omitted.

### Third Embodiment

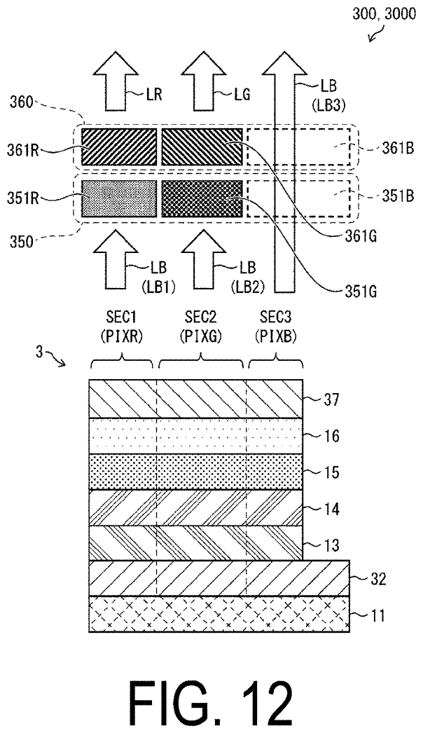

FIG. 12 is a diagram for describing a display device 3000 according to a third embodiment. The light-emitting device and the electroluminescent element of the display device 3000 are referred to as a light-emitting device 300 and an electroluminescent element 3, respectively. The electroluminescent element 3 has a configuration generally similar to that of the electroluminescent element 2. However, unlike the electroluminescent element 2, the electroluminescent element 3 is the TE-type electroluminescent element. In the example illustrated in FIG. 12, a display portion (not illustrated) of the display device 3000 is provided above the electroluminescent element 3.

Specifically, unlike the anode electrode 12, the anode electrode (hereinafter, the anode electrode 32) (the first electrode) of the electroluminescent element 3 is formed as a light-reflective electrode (an electrode similar to the cathode electrode 17). In contrast, unlike the cathode electrode 17, the cathode electrode (hereinafter, the cathode electrode 37) (the second electrode) of the electroluminescent element 3 is formed as a light-transmissive electrode (an electrode similar to the anode electrode 12). By providing the anode electrode 32 and the cathode electrode 37 in this way, the electroluminescent element 3 of the TE-type can be configured. In the electroluminescent element 3, a substrate having low light-transmittance (e.g., a plastic substrate) can be used as the substrate 11.

A wavelength conversion sheet 350 and a CF sheet 360 illustrated in FIG. 12 are a wavelength conversion sheet and a CF sheet, respectively, of the light-emitting device 300. A red wavelength conversion layer 351R is a red wavelength conversion layer of the wavelength conversion sheet 350, and a green wavelength conversion layer 351G is a green wavelength conversion layer of the wavelength conversion sheet 350. A blue light transmission layer 351B is a blue light transmission layer of the wavelength conversion sheet 350. A red CF 361R is a red CF of the CF sheet 360, and a green CF 361G is a green CF of the CF sheet 360. A blue light transmission layer 361B is a blue light transmission layer of the CF sheet 360.

In the light-emitting device 300, since the electroluminescent element 3 is the TE-type, the wavelength conversion sheet 350 and the CF sheet 360 are disposed above the electroluminescent element 3. The third embodiment also provides similar effects to those of the second embodiment. In addition, as described above, according to the electroluminescent element 3, the EQE can be improved as compared with the electroluminescent element 2 (the BE-type electroluminescent element).

### Modified Example

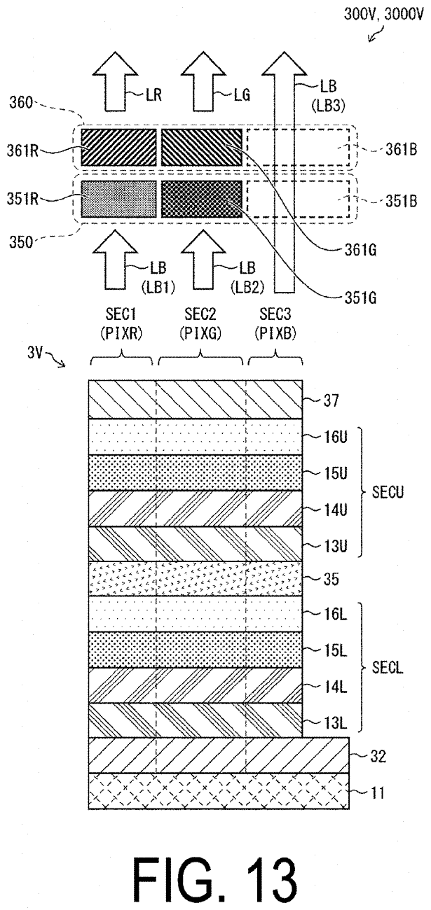

FIG. 13 is a diagram for describing a modified example of the display device 3000 (hereinafter, a display device 3000V). The light-emitting device and the electroluminescent element of the display device 3000V are referred to as a light-emitting device 300V and an electroluminescent element 3V, respectively. The electroluminescent element 3V is a tandem-type electroluminescent element configured based on the electroluminescent element 3. In this manner, the tandem structure can also be adopted in a TE-type electroluminescent element in a similar manner to that in the example illustrated in FIG. 11 (the electroluminescent element 2V).

Note that in the display device described above, by using the non-Cd-based material for the red QD phosphor particles (the red quantum dots), the green QD phosphor particles (the green quantum dots), and the blue QD phosphor particles (the blue quantum dots), an effect of being possible to provide an environment-friendly display device is exerted.

The disclosure is not limited to the embodiments described above, and various modifications may be made within the scope of the claims. Embodiments obtained by appropriately combining technical approaches disclosed in the different embodiments also fall within the technical scope of the disclosure. Moreover, novel technical features may be formed by combining the technical approaches stated in each of the embodiments.

### REFERENCE SIGNS LIST

1, 2, 2U, 2V, 3, 3V Electroluminescent element
12, 32 Anode electrode (anode, first electrode)
3, 13L, 13U Hole injection layer
14 Hole transport layer
15, 15L, 15U QD layer (quantum dot light-emitting layer)
16, 16L, 16U Electron transport layer
17, 37 Cathode electrode
25 QD phosphor particle (quantum dot)
25a Core
25b Shell

1: An electroluminescent element comprising:
an anode electrode;
a cathode electrode; and
a quantum dot light-emitting layer including quantum dots and provided between the anode electrode and the cathode electrode,
wherein the quantum dots are Cd-free quantum dots including at least Zn and Se and not including Cd at a mass ratio of 1/30 or greater in relation to Zn, and
a particle size of each quantum dot is within a range from 3 nm to 20 nm.

2: The electroluminescent element according to claim 1,
wherein the quantum dot includes a core and a shell covering the core, and the core includes at least Zn and Se, and
the thickness of the shell is from 0.3 nm to less than 10 nm.

3: The electroluminescent element according to claim 2,
wherein the thickness of the shell is from 0.3 nm to 3.3 nm.

4: The electroluminescent element according to claim 2,
wherein the thickness of the shell is from 0.5 nm to 3.3 nm.

5: The electroluminescent element according to claim 2,
wherein the thickness of the shell is from 0.8 nm to 3.3 nm.

6: The electroluminescent element according to claim 2,
wherein the thickness of the shell is from 1.0 nm to 2.8 nm.

7: The electroluminescent element according to claim 2,
wherein the thickness of the shell is from 0.8 nm to 1.7 nm.

8: The electroluminescent element according to claim 2,
wherein the thickness of the shell is from 1.0 nm to 1.7 nm.

9: The electroluminescent element according to claim 1,
wherein a fluorescence lifetime of the quantum dots is 50 ns or less.

10: The electroluminescent element according to claim 1,
wherein a fluorescence quantum yield of the quantum dots is 5% or greater, and a fluorescence full-width at half-maximum of the quantum dots is 25 nm or less.

11: The electroluminescent element according to claim 1,
wherein a hole injection layer and a hole transport layer are provided in this order from the anode electrode side, between the anode electrode and the quantum dot light-emitting layer,
the hole injection layer includes a composite of poly(3,4-ethylenedioxythiophene) and polystyrene sulfonic acid, and
the hole transport layer includes poly(N-vinylcarbazole).

12: The electroluminescent element according to claim 11,
wherein a layer thickness of the hole transport layer is within a range from 15 nm to 40 nm.

13: The electroluminescent element according to claim 1, further comprising:
an electron transport layer between the cathode electrode and the quantum dot light-emitting layer,
wherein the electron transport layer includes ZnMgO.
